(19) United States
(12) Patent Application Publication
(10) Pub. No.: US 2026/0334330 A1
(43) Pub. Date: Oct. 22, 2026

(54) SEMICONDUCTOR MEMORY PACKAGE INCLUDING SEMICONDUCTOR MEMORY CHIP HAVING INTERNAL CIRCUIT AND BUFFER CIRCUIT, AND STORAGE DEVICE INCLUDING THE SAME

(71) Applicant: SAMSUNG ELECTRONICS CO., LTD., Suwon-si (KR)

(72) Inventors: Seongjin SONG, Suwon-si (KR); Wandong KIM, Suwon-si (KR); Kiwhan SONG, Suwon-si (KR); Youngseok JEONG, Suwon-si (KR); Youngha CHOI, Suwon-si (KR); Seunghwan SONG, Suwon-si (KR); Hyunee LEE, Suwon-si (KR)

(73) Assignee: SAMSUNG ELECTRONICS CO., LTD., Suwon-si (KR)

(21) Appl. No.: 19/549,931

(22) Filed: Feb. 25, 2026

(30) Foreign Application Priority Data
Apr. 16, 2025 (KR) 10-2025-0049764

(51) Int. Cl. H10W 90/24; G11C 7/10; H10B 80/00; H10D 80/30; H10W 72/50; H10W 90/00

(52) U.S. Cl. CPC H10W 90/24; G11C 7/1057; G11C 7/1084; H10B 80/00; H10D 80/30; H10W 72/5473; H10W 90/752; H10W 90/754

(57) ABSTRACT

A semiconductor memory package includes a base substrate connected to a memory controller and a plurality of semiconductor memory chips stacked on the base substrate, where a first semiconductor memory chip of the plurality of semiconductor memory chips includes a first normal chip pad, a first buffering chip pad, an internal circuit connected to the first normal chip pad, the internal circuit including a memory cell array and a peripheral circuit configured to control the memory cell array and a buffer circuit connected between the first normal chip pad and the first buffering chip pad, the buffer circuit being configured to reinforce a signal transferred between the first normal chip pad and the first buffering chip pad.

### CROSS-REFERENCE TO RELATED APPLICATION

This application is based on and claims priority under 35 USC § 119 to Korean Patent Application No. 10-2025-0049764, filed on Apr. 16, 2025, in the Korean Intellectual Property Office, the disclosure of which is incorporated by reference herein in its entirety.

### BACKGROUND

The present disclosure relates to semiconductor integrated circuits, and more particularly to a semiconductor memory package including stacked semiconductor memory chips and a storage device including the semiconductor memory package.

A semiconductor memory package in the related art may have a structure in which semiconductor chips (or semiconductor dies) are stacked in a vertical direction. For example, a semiconductor memory package may include a plurality of semiconductor memory chips stacked on a substrate such as a printed circuit board (PCB). By connecting the connection pads disposed on the semiconductor memory chips with bonding wires, the semiconductor chips may be electrically connected to each other.

In recent years, the electronics market has seen a dramatic increase in the demand for portable devices, which has led to a continuous need for miniaturization and weight decreasing of the electronic components in these products. To realize the miniaturization and lightweight of these electronic components, not only technologies that reduce the individual size of the mounting components are required, but also semiconductor package technologies that integrate multiple individual devices into a single package are required. In particular, semiconductor memory packages that handle high-frequency signals require not only miniaturization but also excellent electrical characteristics.

The substrate on which the semiconductor memory chips are stacked may include buffer chips that mediate signal transferred between a memory controller and the semiconductor memory chips. These buffer chips increase the size of the semiconductor memory package and reduce design margins.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor memory package and a storage device including a semiconductor memory package including a buffer circuit inside the semiconductor memory chip to replace a buffer chip on a base substrate.

Additional aspects will be set forth in part in the description which follows and, in part, will be apparent from the description, or may be learned by practice of the presented embodiments.

According to an aspect of an example embodiment, a semiconductor memory package may include a base substrate connected to a memory controller and a plurality of semiconductor memory chips stacked on the base substrate, where a first semiconductor memory chip of the plurality of semiconductor memory chips may include a first normal chip pad, a first buffering chip pad, an internal circuit connected to the first normal chip pad, the internal circuit including a memory cell array and a peripheral circuit configured to control the memory cell array and a buffer circuit connected between the first normal chip pad and the first buffering chip pad, the buffer circuit being configured to reinforce a signal transferred between the first normal chip pad and the first buffering chip pad.

According to an aspect of an example embodiment, a semiconductor memory package may include a base substrate connected to a memory controller, and a plurality of semiconductor memory chips stacked on the base substrate, where the plurality of semiconductor memory chips may include a buffering semiconductor memory chip including a buffer circuit configured to reinforce a received signal and transfer a reinforced signal to the base substrate or another semiconductor memory chip among the plurality of semiconductor memory chips and a bypassing semiconductor memory chip that does not include a buffer circuit and is configured to transfer the received signal to the base substrate or another semiconductor memory chip among the plurality of semiconductor memory chips.

According to an aspect of an example embodiment, a storage device may include a semiconductor memory package, and a memory controller configured to control the semiconductor memory package, where the semiconductor memory package may include a base substrate connected to the memory controller, and a plurality of semiconductor memory chips stacked on the base substrate, and where a first semiconductor memory chip of the plurality of semiconductor memory chips may include a normal chip pad, a buffering chip pad, an internal circuit connected to the normal chip pad, the internal circuit including a memory cell array and a peripheral circuit configured to control the memory cell array, and a buffer circuit connected between the normal chip pad and the buffering chip pad, the buffer circuit being configured to reinforce a signal transferred between the normal chip pad and the buffering chip pad.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view illustrating a semiconductor memory package according to example embodiments;

FIG. 2 is a plan view of the semiconductor memory package of FIG. 1 according to example embodiments;

FIG. 3 is a cross-sectional view of the semiconductor memory package of FIG. 1 according to example embodiments;

FIG. 4 is a block diagram illustrating a semiconductor memory chip included in a semiconductor memory package according to example embodiments;

FIG. 5 is a diagram illustrating a buffer circuit included in the semiconductor memory chip of FIG. 4 according to example embodiments;

FIG. 6 is a diagram illustrating a buffer included in the buffer circuit of FIG. 5 according to example embodiments;

FIG. 7 is a timing diagram illustrating signal reinforcement by the buffer of FIG. 6 according to example embodiments;

FIG. 8 is a block diagram illustrating a storage device according to example embodiments;

FIG. 9 is a block diagram illustrating a memory controller included in a storage device according to example embodiments;

FIG. 10 is a block diagram illustrating a nonvolatile memory device according to example embodiments;

FIG. 11 is a block diagram illustrating a storage device according to example embodiments;

FIG. 12 is a block diagram illustrating a memory cell array included in the nonvolatile memory device of FIG. 10 according to example embodiments;

FIG. 13 is a circuit diagram illustrating an equivalent circuit of a memory block included in the memory cell array of FIG. 12 according to example embodiments;

FIG. 14 is a perspective view illustrating a semiconductor memory package according to example embodiments;

FIG. 15 is a plan view of the semiconductor memory package of FIG. 14 according to example embodiments;

FIG. 16 is a cross-sectional view of the semiconductor memory package of FIG. 14 according to example embodiments;

FIG. 17 is a perspective view illustrating a semiconductor memory package according to example embodiments;

FIG. 18 is a plan view of the semiconductor memory package of FIG. 17 according to example embodiments;

FIG. 19 is a cross-sectional view of the semiconductor memory package of FIG. 17 according to example embodiments;

FIG. 20 is a perspective view illustrating a semiconductor memory package according to example embodiments;

FIG. 21 is a plan view of the semiconductor memory package of FIG. 20 according to example embodiments;

FIG. 22 is a cross-sectional view of the semiconductor memory package of FIG. 20 according to example embodiments;

FIGS. 23 and 24 are block diagrams illustrating semiconductor memory chips included in a semiconductor memory package according to example embodiments;

FIGS. 25, 26, 27, 28, 29, 30 and 31 are diagrams illustrating examples of controlling the operation of a semiconductor memory package according to example embodiments;

FIGS. 32 and 33 are diagrams illustrating a semiconductor memory chip included in a semiconductor memory package according to example embodiments;

FIGS. 34 and 35 are diagrams illustrating a semiconductor memory package according to example embodiments;

FIG. 36 is a cross-sectional diagram illustrating a nonvolatile memory device according to example embodiments; and

FIG. 37 is a diagram illustrating manufacturing processes of a nonvolatile memory device according to example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

In this disclosure, two directions parallel to a top surface of a base substrate and intersecting each other are defined as a first direction D1 and a second direction D2, and a direction substantially perpendicular to the top surface of the base substrate is defined as a third direction D3. For example, the first direction D1 and the second direction D2 may intersect substantially perpendicular to each other. The third direction D3 may also be referred to as a vertical direction, the first direction D1 as a first horizontal direction, and the second direction D2 as a second horizontal direction. The definitions of the aforementioned directions are the same in all subsequent drawings.

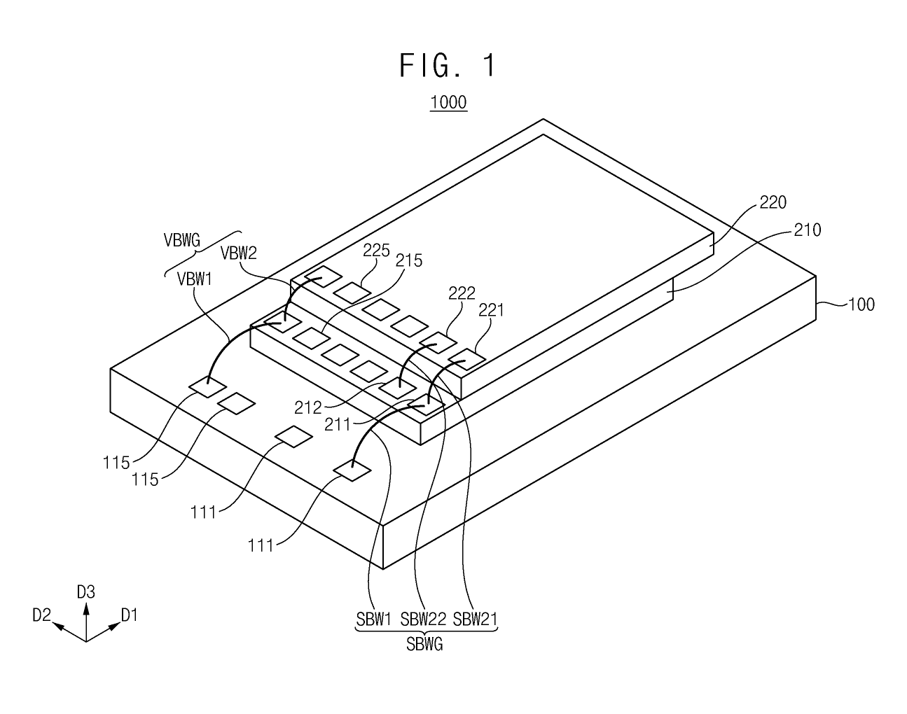

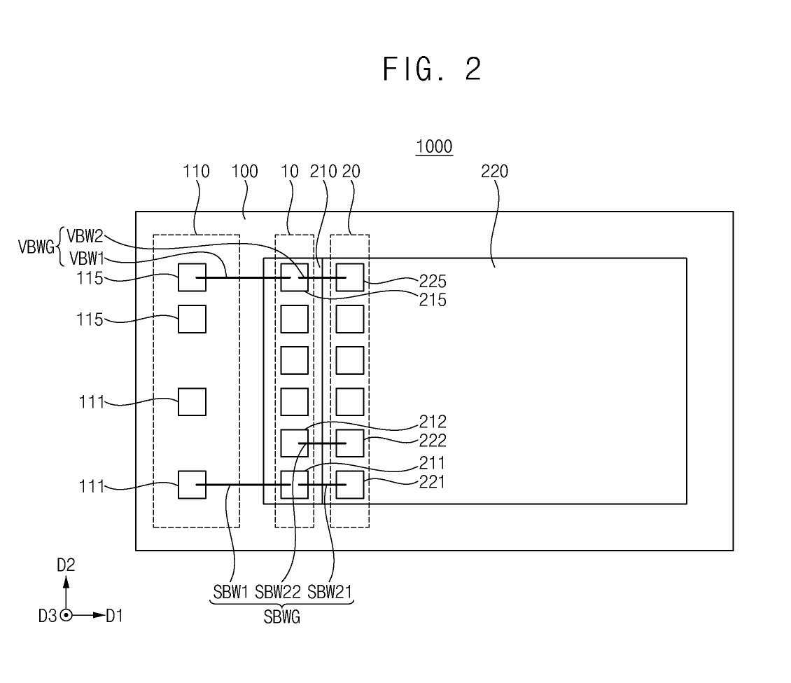

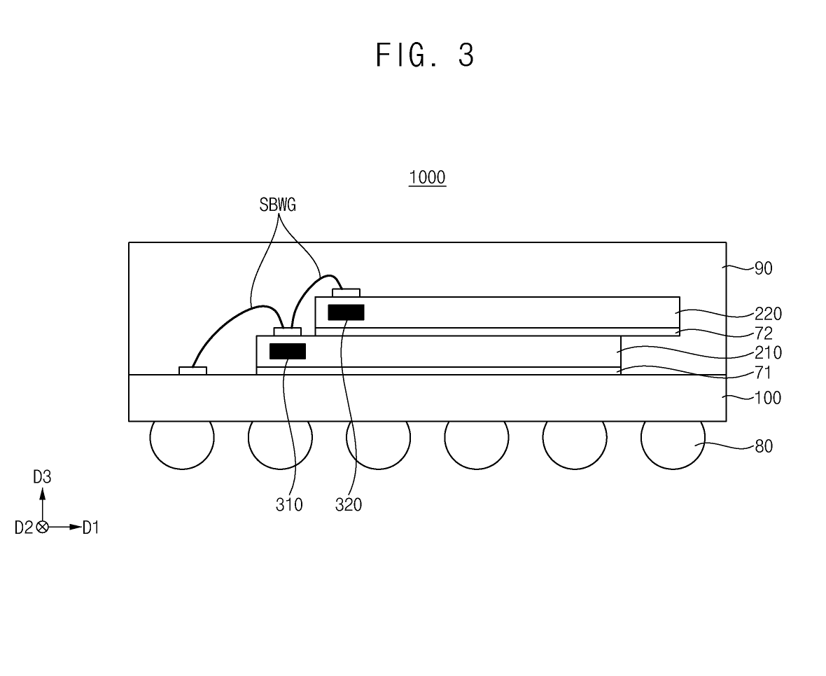

FIG. 1 is a perspective view illustrating a semiconductor memory package according to example embodiments. FIG. 2 is a plan view of the semiconductor memory package of FIG. 1, and FIG. 3 is a cross-sectional view of the semiconductor memory package of FIG. 1.

Referring to FIGS. 1-3, a semiconductor memory package 1000 may include a base substrate 100, a first semiconductor memory chip 210, and a second semiconductor memory chip 220. FIGS. 1-3 illustrate a structure in which two semiconductor memory chips are stacked. Depending on example embodiments, the number of semiconductor memory chips stacked within the semiconductor memory package may vary, such as two, four, eight, sixteen, or the like.

The base substrate 100 may include substrate pads 110. The substrate pads 110 may include substrate voltage pads 115 to which a power supply voltage or ground voltage is applied, and substrate input and output (I/O) pads 111 for transmitting and receiving signals such as data signals, control signals, and the like. The base substrate 100 may be a printed circuit board (PCB), interposer, or the like having conductive lines disposed at surfaces, interior, or the like.

In an example embodiment, a power supply voltage or ground voltage is applied to external terminals 80 from an external device, and the substrate voltage pads 115 may be electrically connected to the external terminals 80 where the power supply voltage or ground voltage is applied via conductive paths formed at the base substrate 100.

The first semiconductor memory chip 210 may be stacked on the base substrate 100 in the vertical direction D3 and may include first chip pads 10. The first chip pads 10 may include first chip voltage pads 215 for carrying the power supply voltage or ground voltage, and first chip I/O pads 211 and 212 for transmitting and receiving signals. The first chip I/O pad 211 may correspond to a buffering chip pad and the first chip I/O pad 212 may correspond to a normal chip pad.

The second semiconductor memory chip 220 may be stacked on the first semiconductor memory chip 210 in the vertical direction D3 and may include second chip pads 20. The second chip pads 20 may include second chip voltage pads 225 for carrying the power supply voltage or ground voltage, and second chip I/O pads 221 and 222 for transmitting and receiving signals. The second chip I/O pad 221 may correspond to a buffering chip pad and the second chip I/O pad 222 may correspond to a normal chip pad.

Each substrate voltage pad 115 may be a pad to which the power supply voltage is commonly applied or the ground voltage is commonly applied.

A first voltage bonding wire VBW1 may connect the substrate voltage pad 115 of the substrate pads 110 to which the power supply voltage or ground voltage is applied and the first chip voltage pad 215 of the first chip pads 10. A second voltage bonding wire VBW2 may connect the first chip voltage pad 215 of the first chip pads 10 and the second chip voltage pad 225 of the second chip pads 20.

The first voltage bonding wire VBW1 and the second voltage bonding wire VBW2 may be referred to as a voltage bonding wire group VBWG. While one voltage bonding wire group VBWG is shown in FIGS. 1, 2, and 3 for convenience of illustration, the semiconductor memory package 1000 may include multiple voltage bonding wire groups having the same structure as the voltage bonding wire group VBWG.

The semiconductor memory package 1000 may include a first signal bonding wire SBW1, a second signal bonding wire SBW21, and a third signal bonding wire SBW22.

The first signal bonding wire SBW1 may connect the substrate I/O pad 111 of the substrate pads 110 and the buffering chip pad 211 of the first semiconductor memory chip 210.

As such, the buffering chip pad 211 of the first semiconductor memory chip 210, which is disposed lowermost in the vertical direction D3 of the plurality of semiconductor memory chips 210 and 220 stacked inside the semiconductor memory package 1000, may be connected to the substrate I/O pad 111 of the base substrate 100. On the other hand, the normal chip pad 212 of the first semiconductor memory chip 210 may not be connected to the substrate I/O pad 111 of the base substrate 100.

The second signal bonding wire SBW21 may connect the buffering chip pad 211 of the first semiconductor memory chip 210 and the buffering chip pad 221 of the second semiconductor memory chip 220. The third signal bonding wire SBW22 may connect the normal chip pad 212 of the first semiconductor memory chip 210 and the normal chip pad 222 of the second semiconductor memory chip 220.

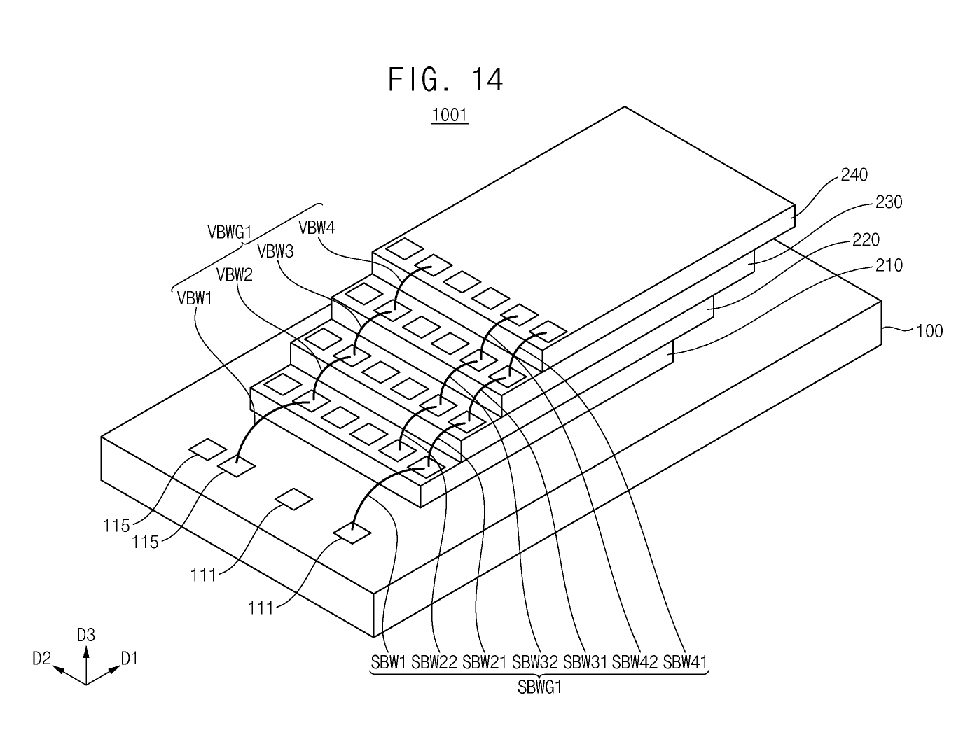

FIGS. 1-3 illustrate an example embodiment of connecting the pads of stacked semiconductor memory chips 210 and 220. As will be described below with reference to FIGS. 14-22, various example embodiments of pad connections of the stacked semiconductor memory chips 210 and 220 may be implemented.

The first signal bonding wire SBW1, the second signal bonding wire SBW21, and the third signal bonding wire SBW22 may be referred to as a signal bonding wire group SBWG. While one signal bonding wire group SBWG is illustrated in FIGS. 1-3 for convenience of illustration, the semiconductor memory package 1000 may include multiple signal bonding wire groups having the same structure as the signal bonding wire group SBWG.

FIGS. 1-3 illustrate example embodiments in which the pads of the base substrate 100, the first semiconductor memory chip 210, and the second semiconductor memory chip 220 are connected to each other using bonding wires. According to example embodiments, at least some of the pads may be connected to each other via other conductive pathways other than bonding wires, such as through-silicon vias (TSVs).

The base substrate 100 and the semiconductor memory chips 210 and 220 may be stacked using bonding layers 71 and 72. The first semiconductor memory chip 210 may be bonded to the top surface of the base substrate 100 via the first bonding layer 71, and the second semiconductor memory chip 220 may be bonded to the top surface of the first semiconductor memory chip 210 via the second bonding layer 72.

The external terminals 80 may be provided on the bottom surface of the base substrate 100. The external terminals 80 may include solder balls or solder pads, and depending on the type of external terminals 80, the semiconductor memory package 1000 may include a ball grid array (BGA), a fine ball-grid array (FBGA), a land grid array (LGA), or the like.

A molding film 90 may be provided to cover the top surface of the base substrate 100 and the semiconductor memory chips 210 and 220. The molding film 90 may include an insulating polymeric material, such as an epoxy molding compound (EMC).

As shown in FIGS. 1-3, the substrate pads 110 may be arranged along the second horizontal direction D2 at an end portion in the first horizontal direction D1 of the base substrate 100. The first chip pads 10 may be arranged along the second horizontal direction D2 at an end portion of the first horizontal direction D1 of the first semiconductor memory chip 210. The second chip pads 20 may be arranged along the second horizontal direction D2 at an end portion of the first horizontal direction D1 of the second semiconductor memory chip 220.

The second semiconductor memory chip 220 may be shifted in the first horizontal direction D1 than the first semiconductor memory chip 210 such that the first chip pads 10 are exposed facing the vertical direction D3, that is, such that the second semiconductor memory chip 220 stacked on the first semiconductor memory chip 210 does not cover the first chip pads 10. In other words, the first semiconductor memory chip 210 and the second semiconductor memory chip 220 may be stacked in a stepped structure, such that thee second semiconductor memory chip 220 is on the first semiconductor memory chip 210 and extends over an end of the first semiconductor memory chip 210 in the first direction D1.

According to example embodiments, at least one of a plurality of semiconductor memory chips stacked within a semiconductor memory package may include a buffer circuit. In an example embodiment, as shown in FIG. 3, a first semiconductor memory chip 210 may include a first buffer circuit 310, and a second semiconductor memory chip 220 may include a second buffer circuit 320. FIG. 3 illustrates an example embodiment in which the stacked semiconductor memory chips each include a buffer circuit. For example, the second buffer circuit 320 included in the second semiconductor memory chip 220 may be omitted. In this case, the semiconductor memory chip including the buffer circuit may be referred to as a buffering semiconductor memory chip, and the semiconductor memory chip not including the buffer circuit may be referred to as a bypassing semiconductor memory chip.

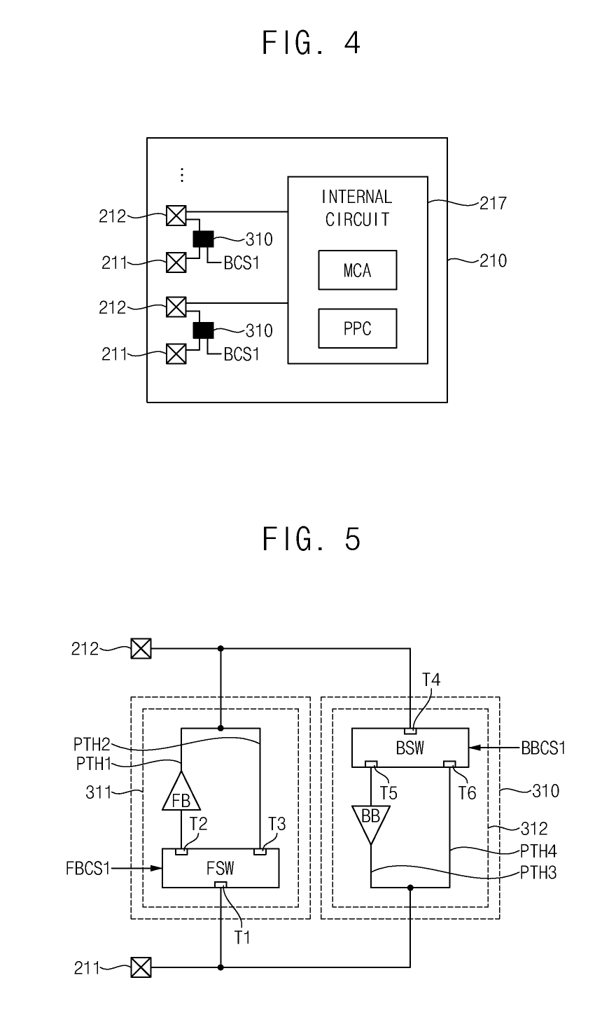

FIG. 4 is a block diagram illustrating an example embodiment of a semiconductor memory chip included in a semiconductor memory package according to example embodiments.

The first semiconductor memory chip 210 is shown in FIG. 4, which corresponds to a buffering semiconductor memory chip including the buffer circuit 310 for convenience of illustration and description. Other buffering semiconductor memory chips stacked in a semiconductor memory package may be implemented in substantially the same configuration as the first semiconductor memory chip 210.

Referring to FIG. 4, the first semiconductor memory chip 210 may include the normal chip pad 212, the buffering chip pad 211, the internal circuit 217, and the buffer circuit 310.

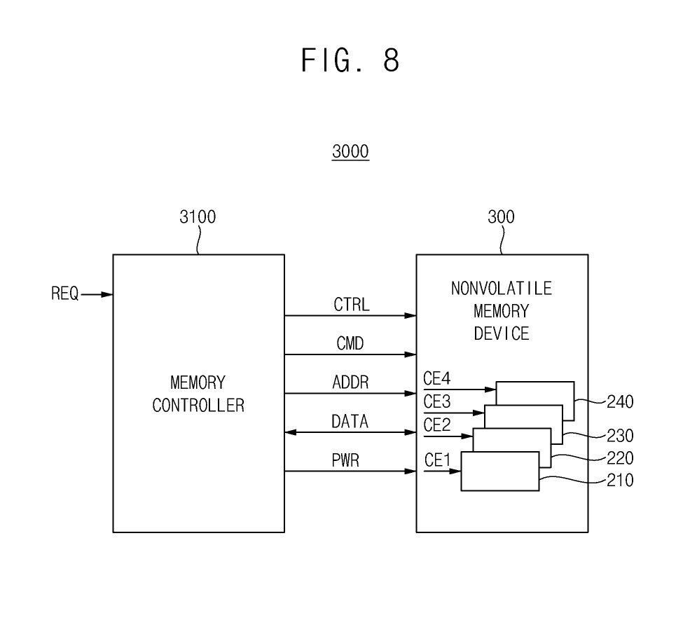

The internal circuit 217 may include the memory cell array MCA and the peripheral circuit PPC that controls the memory cell array MCA. The internal circuit 217 may be connected to the normal chip pad 212. Example embodiments of configuration and operation of the internal circuit 217 will be described below with reference to FIGS. 8-13.

The buffer circuit 310 may be connected between the normal chip pad 212 and the buffering chip pad 211, and may reinforce or enhance signals transferred between the normal chip pad 212 and the buffering chip pad 211. As will be described below, the buffer circuit 310 may selectively reinforce the signal transferred between the normal chip pad 212 and the buffering chip pad 211 based on a buffering control signal BCS1.

FIG. 5 is a diagram illustrating a buffer circuit included in the semiconductor memory chip of FIG. 4 according to example embodiments.

Referring to FIG. 5, the buffer circuit 310 may include a forward buffer circuit 311 and a backward buffer circuit 312. The forward buffer circuit 311 may selectively reinforce signals transferred from the buffering chip pad 211 to the normal chip pad 212 based on a forward buffering control signal FBCS1. The backward buffer circuit 312 may selectively reinforce the signal transferred from the normal chip pad 212 to the buffering chip pad 211 based on a backward buffering control signal BBCS1. In an example embodiment, as shown in FIG. 5, the forward buffer circuit 311 and the backward buffer circuit 312 may include buffers and switch circuits, respectively.

The forward buffer circuit 311 may include a forward buffer FB and a forward switch circuit FSW.

The output of the forward buffer FB may be connected to the normal chip pad 212. The forward switch circuit FSW may include a first terminal T1 connected to the buffering chip pad 211, a second terminal T2 connected to an input of the forward buffer FB, and a third terminal T3 connected to the normal chip pad 212. The forward switch circuit FSW may selectively connect the first terminal T1 to the second terminal T2 or the third terminal T3 based on the forward buffering control signal FBCS1. For example, the forward switch circuit FSW may select a first path PTH1 including the forward buffer FB by connecting the first terminal T1 to the second terminal T2 when the forward buffering control signal FBCS1 is at a first logic level (e.g., a logic high level). In this case, the forward buffer circuit 311 may reinforce or strengthen the signal transferred from the buffering chip pad 211 to the normal chip pad 212. On the other hand, the forward switch circuit FSW may select a second path PTH2 that does not include a buffer by connecting the first terminal T1 to the third terminal T3 when the forward buffering control signal FBCS1 is at a second logic level (e.g., a logic low level). In this case, the forward buffer circuit 311 may bypass the signal from the buffering chip pad 211 to the normal chip pad 212 without reinforcing the signal.

The backward buffer circuit 312 may include a backward buffer BB and a backward switch circuit BSW.

The output of the backward buffer BB may be connected to the buffering chip pad 211. The backward switch circuit BSW may include a fourth terminal T4 connected to the normal chip pad 212, a fifth terminal T5 connected to the input of the backward buffer BB, and a sixth terminal T6 connected to the buffering chip pad 211. The backward switch circuit BSW may selectively connect the fourth terminal T4 to the fifth terminal T5 or the sixth terminal T6 based on the backward buffering control signal BBCS1. For example, the backward switch circuit BSW may select a third path PTH3 including the backward buffer BB by connecting the fourth terminal T4 to the fifth terminal T5 when the backward buffering control signal BBCS1 is at a first logic level (e.g., a logic high level). In this case, the backward buffer circuit 312 may reinforce or strengthen the signal transferred from the normal chip pad 212 to the buffering chip pad 211. On the other hand, the backward switch circuit BSW may select a fourth path PTH4 that does not include a buffer by connecting the fourth terminal T4 to the sixth terminal T6 when the backward buffering control signal BBCS1 is at a second logic level (e.g., a logic low level). In this case, the backward buffer circuit 312 may bypass the signal from the normal chip pad 212 to the buffering chip pad 211 without reinforcing the signal.

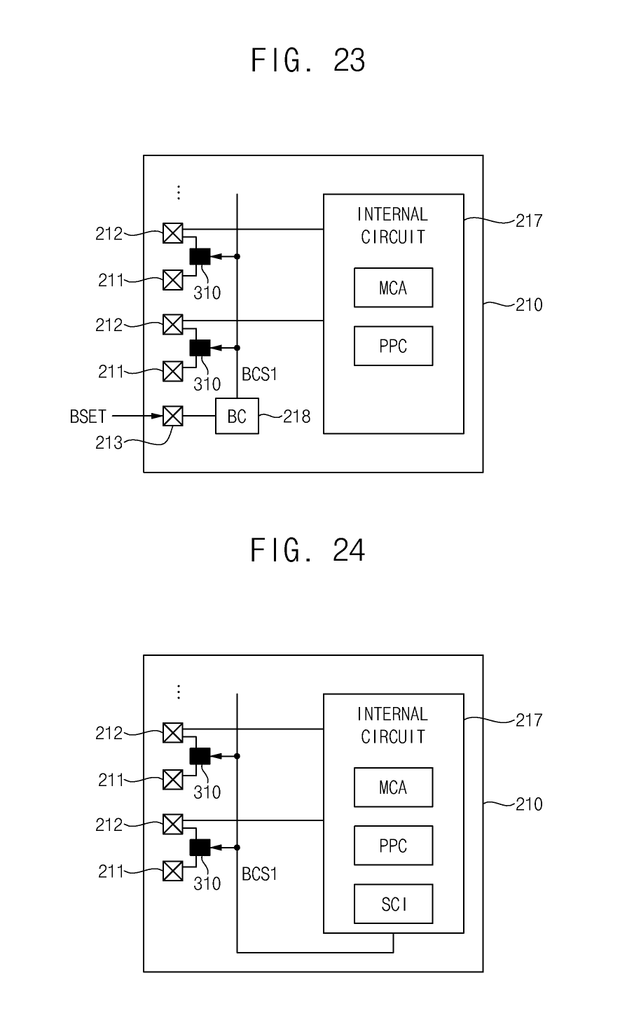

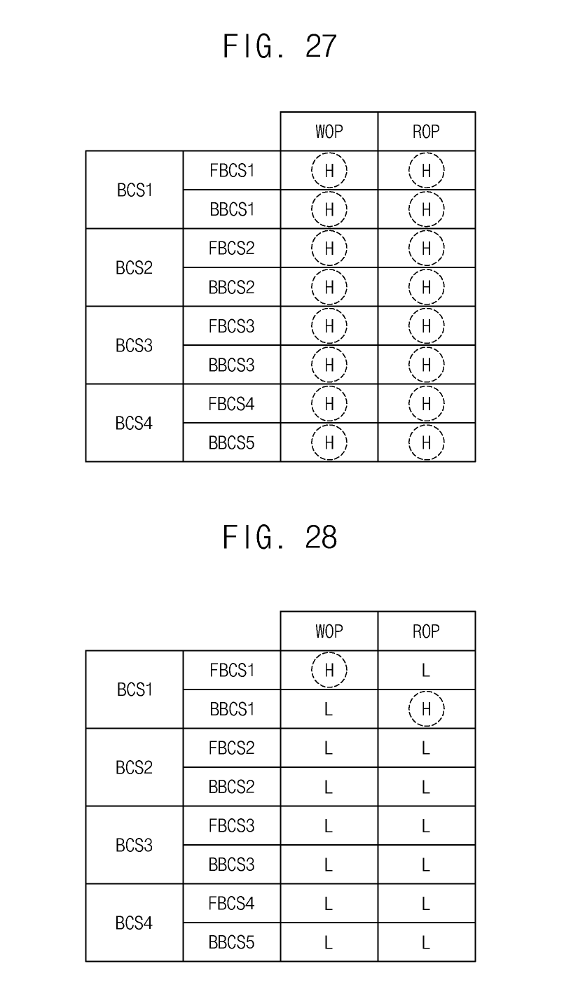

In an example embodiment, as will be described below with reference to FIG. 25, the forward buffering control signal FBCS1 and the backward buffering control signal BBCS1 may be the same signal. In this case, the forward buffer circuit 311 and the backward buffer circuit 312 may be simultaneously enabled or simultaneously disabled. In another example embodiment, as will be described below with reference to FIG. 28, the forward buffering control signal FBCS1 and the backward buffering control signal BBCS1 may be independent signals. In this case, the forward buffer circuit 311 and the backward buffer circuit 312 may be enabled or disabled independently of each other.

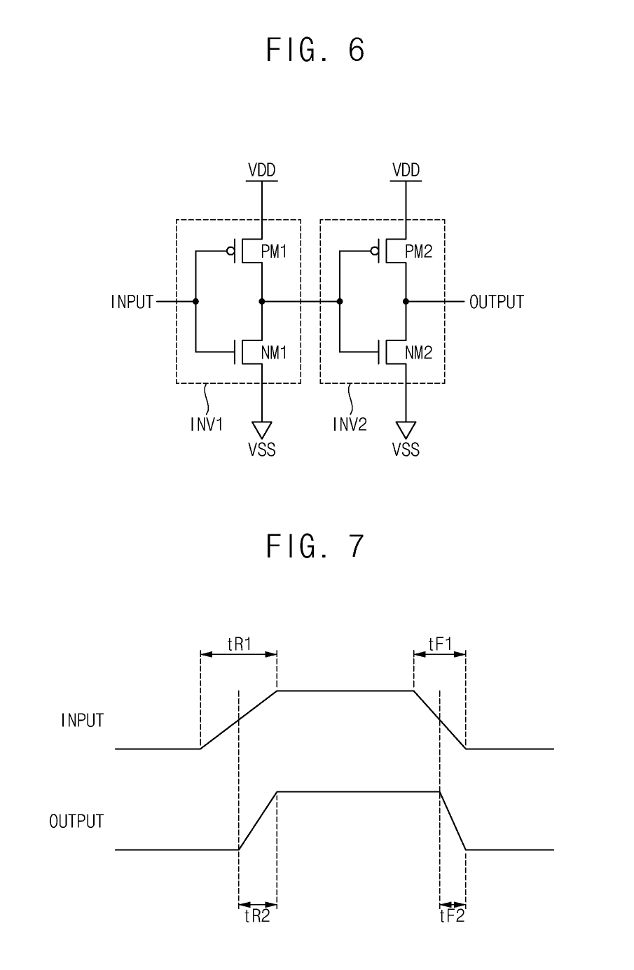

FIG. 6 is a diagram illustrating a buffer included in the buffer circuit of FIG. 5, and FIG. 7 is a timing diagram illustrating signal reinforcement by the buffer of FIG. 6.

Referring to FIG. 6, each of the forward buffer FB and the backward buffer BB of FIG. 5 may include a first inverter INV1 and a second inverter INV2. The first inverter INV1 may include a first p-type metal-oxide-semiconductor (MOS) (PMOS) transistor PM1 and a first n-type MOS (NMOS) transistor NM1, and the second inverter INV2 may include a second PMOS transistor PM2 and a second NMOS transistor NM2. FIG. 6 illustrates an example of two inverters INV1 and INV2 connected in series, but the number of inverters included in the buffer may be varied. Furthermore, FIG. 6 illustrates an inverter in which two transistors are connected between the power supply voltage VDD and the ground voltage VSS, but the number of transistors included in the inverter may be varied.

Referring to FIG. 7, the rising transition time tR2 and falling transition time tF2 of the output of the buffer are less than the rising transition time tR1 and falling transition time tF1 of the input of the buffer. As a result, the input of the buffer may be reinforced with respect to the output of the buffer, and the signal integrity, such as the eye window of the signal transferred through the buffer, may be improved.

FIG. 8 is a block diagram illustrating a storage device according to example embodiments.

Referring to FIG. 8, a storage device 3000 may include a memory controller (or storage controller) 3100 and at least one nonvolatile memory device 300. The storage device 3000 illustrated in FIG. 8 may include a data storage medium based on flash memory, such as a memory card, universal serial bus (USB) memory, solid state drive (SSD), or the like.

The nonvolatile memory device 300 may perform erase, write, or read operations, or the like, under control of the memory controller 3100. The nonvolatile memory device 300 may receive commands CMD such as read commands and write commands, and addresses ADDR such as read addresses and write addresses, from the memory controller 3100 via I/O lines, and may transfer and receive data DATA for the read operations or the write operations (or program operations) with the memory controller 3100. In addition, the nonvolatile memory device 300 may receive a control signal CTRL via a control line, and the nonvolatile memory device 300 may receive power PWR from the memory controller 3100.

The memory controller 3100 may control access to the nonvolatile memory device 300 based on requests REQ received from an external host device.

The nonvolatile memory device 300 may be implemented in the form of a semiconductor memory package in which a plurality of semiconductor memory chips 210, 220, 230 and 240 are stacked, as described with reference to FIGS. 1-3. The plurality of semiconductor memory chips 210, 220, 230 and 240 may be selectively enabled based on each of a plurality of chip enable signals CE1, CE2, CE3 and CE4. If the plurality of semiconductor memory chips 210, 220, 230 and 240 belong to one and the same channel, only one of the plurality of chip enable signals CE1, CE2, CE3 and CE4 may be enabled and the others may be disabled.

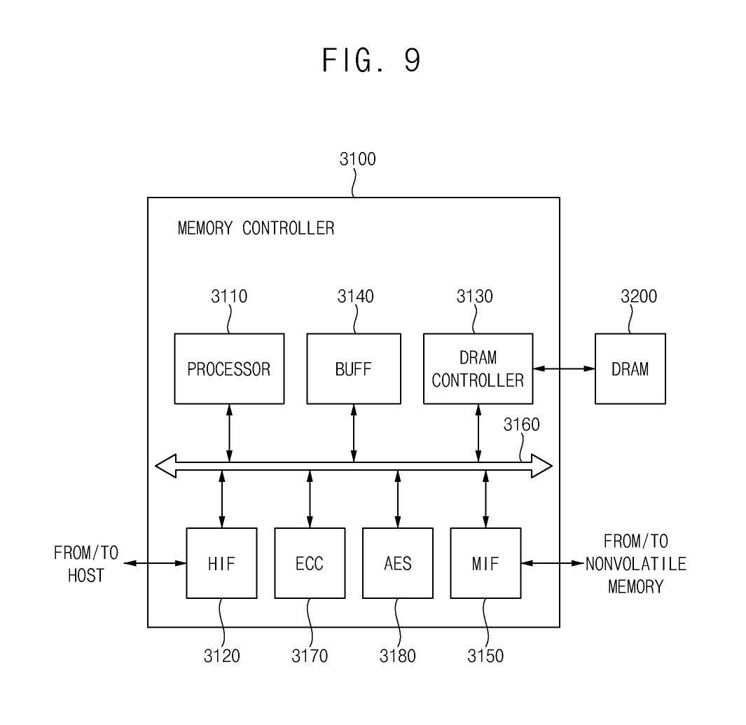

FIG. 9 is a block diagram illustrating a memory controller included in a storage device according to example embodiments.

Referring to FIG. 9, a memory controller or storage controller 3100 may include a processor 3110, a buffer memory (BUFF) 3140, a dynamic random access memory (DRAM) controller 130, a host interface (HIF) 3120, an error correction code (ECC) engine 3170, a memory interface (MIF) 3150, an advanced encryption standard (AES) engine 3180, and an internal bus 3160 electrically connecting the components.

The processor 3110 may control the operation of the memory controller 3100 in response to commands received via the host interface 3120 from an external host device. For example, the processor 3110 may control the operation of a memory system (e.g., the storage device 3000 in FIG. 8) and may employ firmware to drive the memory system to control respective components.

The buffer memory 3140 may store instructions and data that are executed and processed by the processor 3110. For example, the buffer memory 3140 may be implemented as volatile memory, such as static RAM (SRAM), DRAM, or the like.

The ECC engine 3170 for error correction may perform ECC encoding and ECC decoding using error correction code such as Bose-Chaudhuri-Hocquenghem (BCH) code, Low Density Parity Check (LDPC) code, Turbo Code, Reed-Solomon Code, Convolution Code, Recursive Systematic Code (RSC), Coded Modulation, such as Trellis-Coded Modulation (TCM), Block Coded Modulation (BCM), Hamming code, and so on.

The host interface 3120 may provide a physical connection between the host device and the memory controller 3100, i.e., the host interface 3120 may provide interfacing with the memory controller 3100 in a bus format corresponding to the bus format of the host device. In an example embodiment, the bus format of the host device may be SCSI or SAS. In an example embodiment, the bus format of the host device may be USB, peripheral component interconnect express (PCIe), ATA, PATA, SATA, NVMe, or the like.

The memory interface 3150 may exchange data with a nonvolatile memory device (e.g., the nonvolatile memory device 300 in FIG. 8). The memory interface 3150 may transfer write data to the nonvolatile memory device 300, and may receive read data from the nonvolatile memory device 300. For example, the memory interface 3150 may utilize a standard protocol such as Toggle or ONFI.

The AES engine 3180 may perform at least one of encryption operations and decryption operations on data input to the memory controller 3100, using a symmetric-key algorithm. The AES engine 3180 may include an encryption module and a decryption module. Depending on embodiments, the encryption module and the decryption module may be implemented as separate modules or may be implemented as a single module.

The processor 3110 may access the external DRAM 3200 via the DRAM controller 3130. The processor 3110 may control the DRAM controller 3130, the memory interface 3150, and the host interface 3120 to transfer user data stored in the external DRAM 3200 to the nonvolatile memory device 300 or to an external host device.

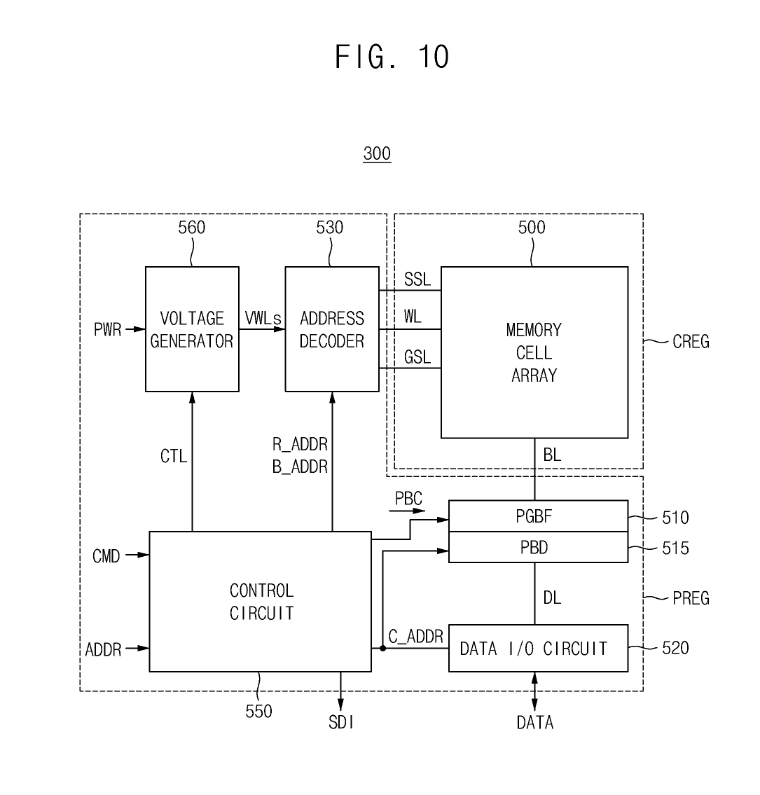

FIG. 10 is a block diagram illustrating a nonvolatile memory device according to example embodiments.

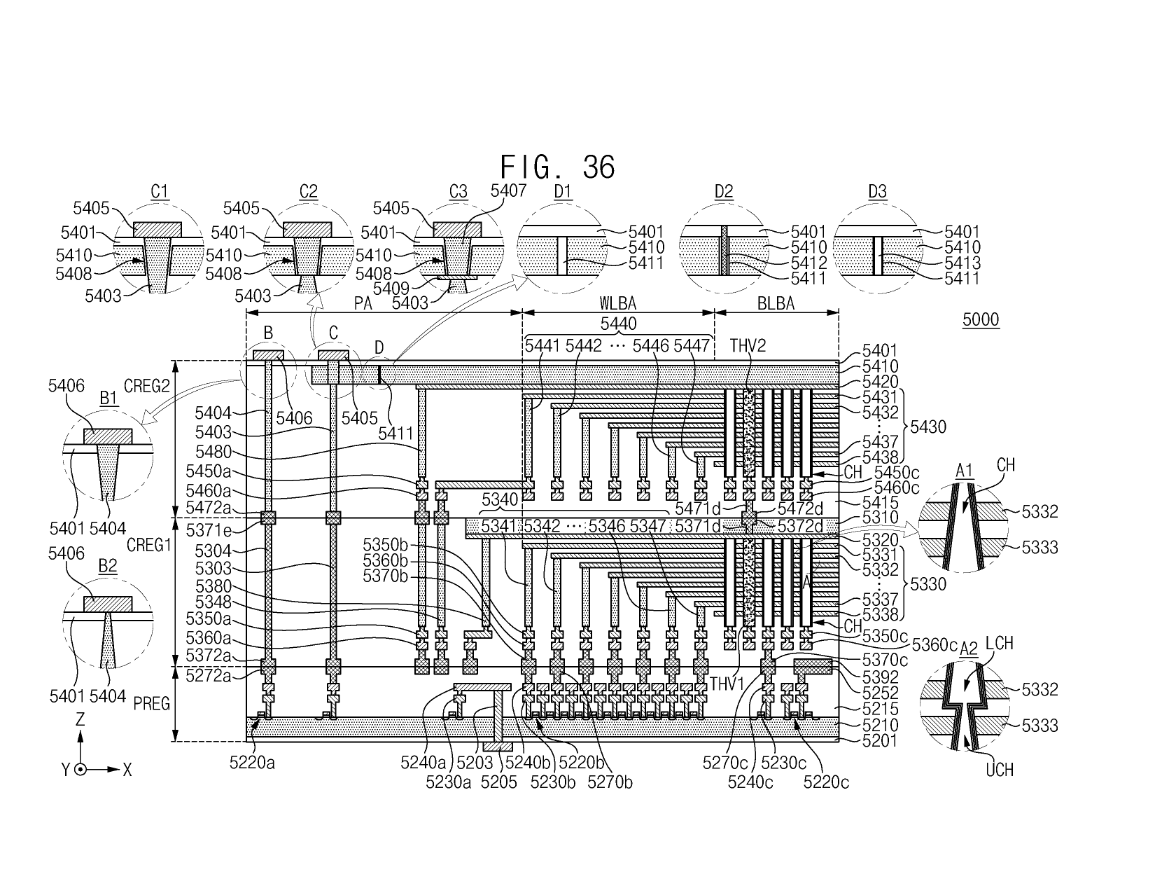

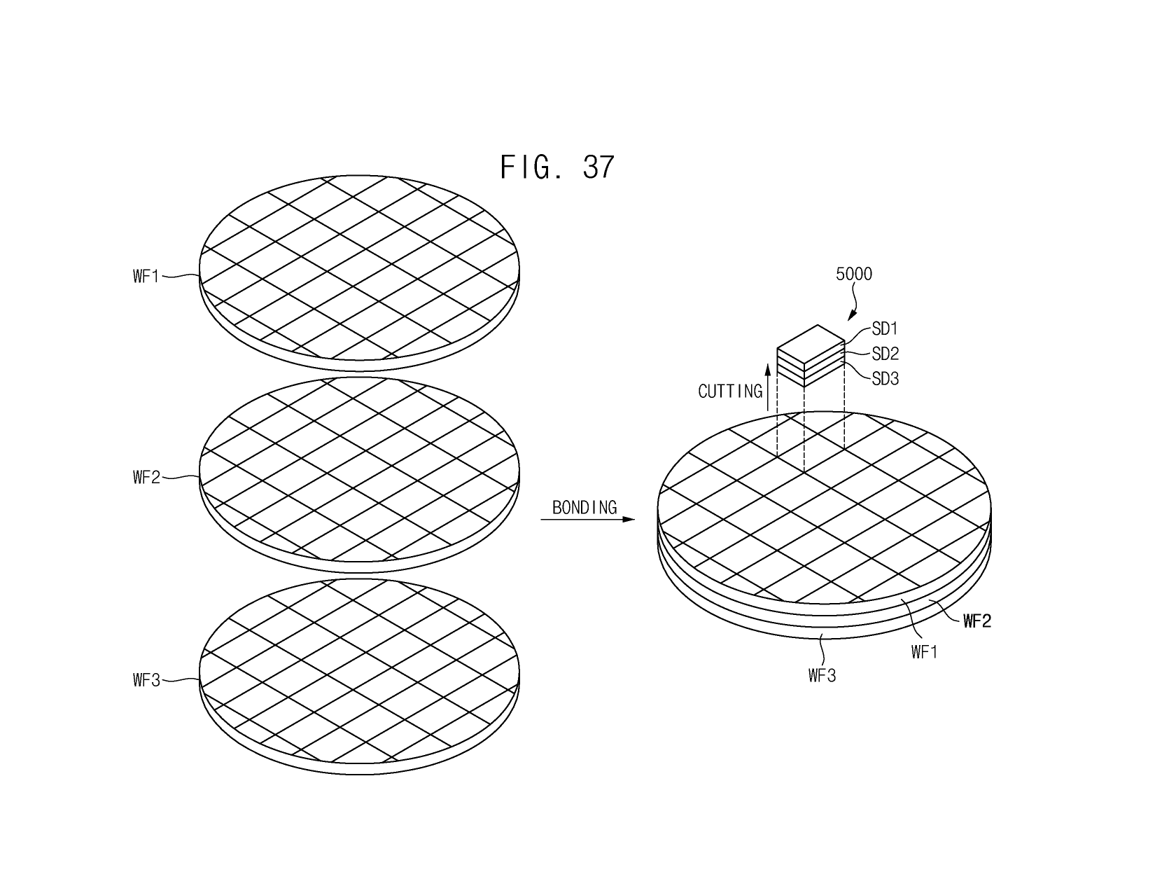

Referring to FIG. 10, a nonvolatile memory device 300 may include a memory cell array 500, a page buffer circuit (PGBF) 510, a page buffer decoder (PBD) 515, a data input-output (I/O) circuit 520, an address decoder 530, a control circuit 550, and a voltage generator 560. As will be described below with reference to FIGS. 36 and 37, in some example embodiments, the cell region CREG and the peripheral region PREC may be formed and disposed in different wafers. In addition, in some example embodiments, the cell region CREG may include a plurality of cell regions that are disposed in different wafers.

The memory cell array 500 may be coupled to the address decoder 530 through string selection lines SSL, wordlines WL, and ground selection lines GSL. In addition, the memory cell array 500 may be coupled to the page buffer circuit 510 through bitlines BL. The memory cell array 500 may include memory cells coupled to the wordlines WL and the bitlines BL. In some example embodiments, the memory cell array 500 may be a three-dimensional memory cell array, which is formed on a substrate in a three-dimensional structure (for example, a vertical structure). In this case, the memory cell array 500 may include cell strings (e.g., NAND strings) that are vertically oriented such that at least one memory cell is overlapped vertically with another memory cell.

The control circuit 550 may receive a command signal CMD and an address signal ADDR from a memory controller. Accordingly, the control circuit 550 may control erase, program and read operations of the nonvolatile memory device 300 in response to (or based on) at least one of the command signal CMD and the address signal ADDR. An erase operation may include performing a sequence of erase loops. A program operation may include performing a sequence of program loops. Each program loop may include a program operation and a program verification operation. Each erase loop may include an erase operation and an erase verification operation. The read operation may include a normal read operation and a data recover read operation.

For example, the control circuit 550 may generate the control signals CTL used to control the operation of the voltage generator 560. The control circuit 550 may also generate the page buffer control signal PBC for controlling the page buffer circuit 510 based on the command signal CMD, and generate the block address B_ADDR, the row address R_ADDR and the column address C_ADDR based on the address signal ADDR. The control circuit 550 may provide the block address B_ADDR and the row address R_ADDR to the address decoder 530 and provide the column address C_ADDR to the data I/O circuit 520.

The address decoder 530 may be coupled to the memory cell array 500 through the string selection lines SSL, the wordlines WL, and the ground selection lines GSL.

During the program operation or the read operation, the address decoder 530 may determine or select one of the wordlines WL as a selected wordline and determine the remaining wordlines WL except for the selected wordline as unselected wordlines based on the row address R_ADDR.

During the program operation or the read operation, the address decoder 530 may determine one of the string selection lines SSL as a selected string selection line and determine the remaining string selection lines SSL except for the selected string selection line as unselected string selection lines based on the row address R_ADDR.

The voltage generator 560 may generate wordline voltages VWLs, which are required for the operation of the memory cell array 500 of the nonvolatile memory device 300, based on the control signals CTL. The voltage generator 560 may receive power PWR from a memory controller such as the memory controller 3100 in FIG. 8. The wordline voltages VWLs may be applied to the wordlines WL through the address decoder 530.

For example, during the erase operation, the voltage generator 560 may apply an erase voltage to a well and/or a common source line of a memory block and apply an erase permission voltage (e.g., a ground voltage) to all or a portion of the wordlines of the memory block based on an erase address. During the erase verification operation, the voltage generator 560 may apply an erase verification voltage simultaneously to all of the wordlines of the memory block or sequentially (e.g., one by one) to the wordlines.

For example, during the program operation, the voltage generator 560 may apply a program voltage to the selected wordline and may apply a program pass voltage to the unselected wordlines. In addition, during the program verification operation, the voltage generator 560 may apply a program verification voltage to the first wordline and may apply a verification pass voltage to the unselected wordlines.

During the normal read operation, the voltage generator 560 may apply a read voltage to the selected wordline and may apply a read pass voltage to the unselected wordlines. During the data recover read operation, the voltage generator 560 may apply the read voltage to a wordline adjacent to the selected wordline and may apply a recover read voltage to the selected wordline.

The page buffer circuit 510 may be coupled to the memory cell array 500 through the bitlines BL. The page buffer circuit 510 may include multiple buffers. In some example embodiments, each buffer may be connected to a single bitline. In some example embodiments, each buffer may be connected to two or more bitlines. The page buffer circuit 510 may temporarily store data to be programmed in a selected page or data read from the selected page of the memory cell array 500.

The page buffer decoder 515 may control the connection between the page buffer circuit 510 and the data lines DL based on the column address C_ADDR provided from the control circuit 550 and column repair information stored therein. The page buffer decoder 515 may perform column repair.

The data I/O circuit 520 may be coupled to the page buffer circuit 510 through data lines DL. During the program operation, the data I/O circuit 520 may receive program data DATA received from the memory controller and provide the program data DATA to the page buffer circuit 510 based on the column address C_ADDR received from the control circuit 550. During the read operation, the data I/O circuit 520 may provide read data DATA, having been read from the memory cell array 500 and stored in the page buffer circuit 510, to the memory controller based on the column address C_ADDR received from the control circuit 550.

In addition, the page buffer circuit 510 and the data I/O circuit 520 may read data from a first area of the memory cell array 500 and write the read data to a second area of the memory cell array 500 (e.g., without transferring the data to a source external to the nonvolatile memory device 300, such as to the memory controller). For example, the page buffer circuit 510 and the data I/O circuit 520 may perform a copy-back operation.

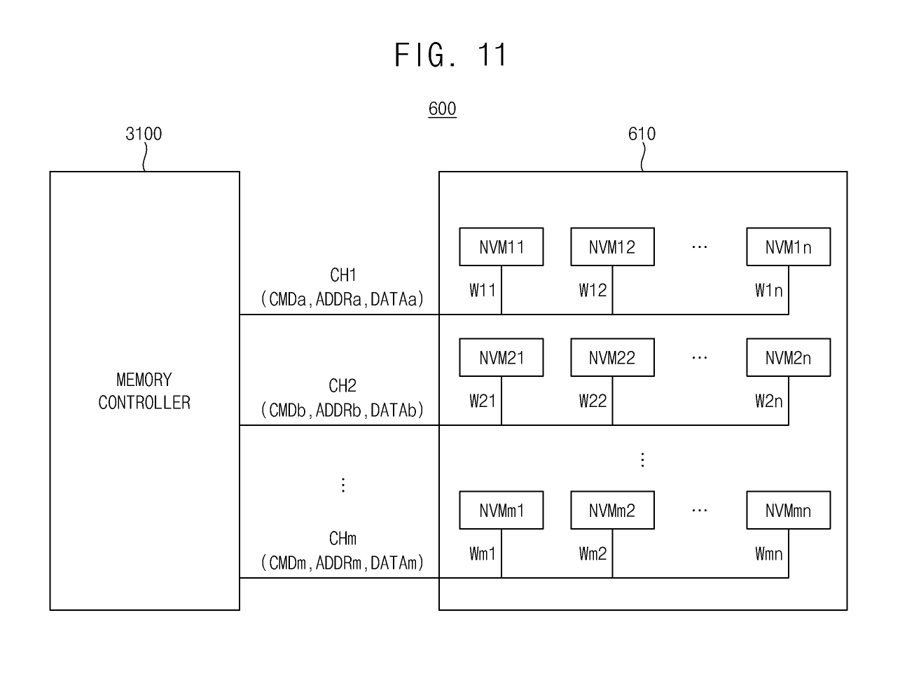

FIG. 11 is a block diagram illustrating a storage device according to example embodiments.

Referring to FIG. 11, a storage device 600 may include a nonvolatile memory device 610 and a memory controller 3100. The storage device 600 may support a plurality of channels CH1, CH2, ..., CHm, and the nonvolatile memory device 610 may be connected to the memory controller 3100 through the plurality of channels CH1 to CHm. For example, the storage device 600 may be implemented as a universal flash storage (UFS), a solid state drive (SSD), or the like. The storage device 600 may correspond to the storage device 3000 of FIG. 8.

The nonvolatile memory device 610 may include a plurality of nonvolatile memories NVM11, NVM12, ..., NVM1n, NVM21, NVM22, ..., NVM2n, NVMm1, NVMm2, ..., NVMmn. Here, n and m may each be integers. Each of the nonvolatile memories NVM11 to NVMmn may be connected to one of the plurality of channels CH1 to CHm through a way corresponding thereto. For example, the nonvolatile memories NVM11 to NVM1n may be connected to the first channel CH1 through ways W11, W12, ..., W1n, the nonvolatile memories NVM21 to NVM2n may be connected to the second channel CH2 through ways W21, W22, ..., W2n, and the nonvolatile memories NVMm1 to NVMmn may be connected to the m-th channel CHm through ways Wm1, Wm2, ..., Wmn. In some example embodiments, each of the nonvolatile memories NVM11 to NVMmn may be implemented as a memory unit that may operate according to an individual command from the memory controller 3100. For example, each of the nonvolatile memories NVM11 to NVMmn may be implemented as a chip or a die, but example embodiments are not limited thereto.

The memory controller 3100 may transmit and receive signals to and from the nonvolatile memory device 610 through the plurality of channels CH1 to CHm. For example, the memory controller 3100 may transmit commands CMDa, CMDb, ..., CMDm, addresses ADDRa, ADDRb, ..., ADDRm and data DATAa, DATAb, ..., DATAm to the nonvolatile memory device 610 through the channels CH1 to CHm, or may receive the data DATAa to DATAm from the nonvolatile memory device 610 through the channels CH1 to CHm.

The memory controller 3100 may select one of the nonvolatile memories NVM11 to NVMmn, which is connected to each of the channels CH1 to CHm, using a corresponding one of the channels CH1 to CHm, and may transmit and receive signals to and from the selected nonvolatile memory. For example, the memory controller 3100 may select the nonvolatile memory NVM11 from among the nonvolatile memories NVM11 to NVM1n connected to the first channel CH1. The memory controller 3100 may transmit the command CMDa, the address ADDRa and the data DATAa to the selected nonvolatile memory NVM11 through the first channel CH1 or may receive the data DATAa from the selected nonvolatile memory NVM11 through the first channel CH1.

The memory controller 3100 may transmit and receive signals to and from the nonvolatile memory device 610 in parallel through different channels. For example, the memory controller 3100 may transmit the command CMDb to the nonvolatile memory device 610 through the second channel CH2 while transmitting the command CMDa to the nonvolatile memory device 610 through the first channel CH1. For example, the memory controller 3100 may receive the data DATAb from the nonvolatile memory device 610 through the second channel CH2 while receiving the data DATAa from the nonvolatile memory device 610 through the first channel CH1.

The memory controller 3100 may control overall operations of the nonvolatile memory device 610. The memory controller 3100 may transmit a signal to the channels CH1 to CHm and may control each of the nonvolatile memories NVM11 to NVMmn connected to the channels CH1 to CHm. For example, the memory controller 3100 may transmit the command CMDa and the address ADDRa to the first channel CH1 and may control one selected from among the nonvolatile memories NVM11 to NVM1n.

Each of the nonvolatile memories NVM11 to NVMmn may operate under the control of the memory controller 3100. For example, the nonvolatile memory NVM11 may program the data DATAa based on the command CMDa, the address ADDRa and the data DATAa provided from the memory controller 3100 through the first channel CH1. For example, the nonvolatile memory NVM21 may read the data DATAb based on the command CMDb and the address ADDRb provided from the memory controller 3100 through the second channel CH2 and may transmit the read data DATAb to the memory controller 3100 through the second channel CH2.

Although FIG. 11 illustrates an example where the nonvolatile memory device 610 communicates with the memory controller 3100 through m channels and includes n nonvolatile memories corresponding to each of the channels, the channel configuration is not limited thereto and the number of channels and the number of nonvolatile memories connected to one channel may be variously changed.

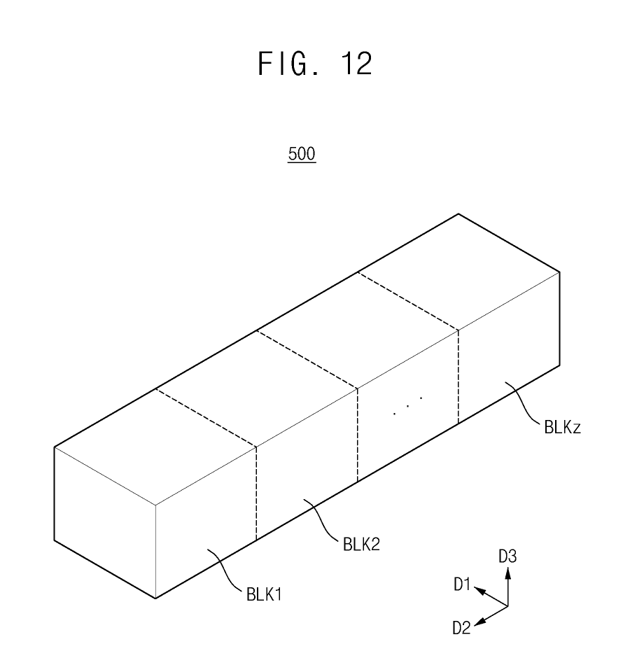

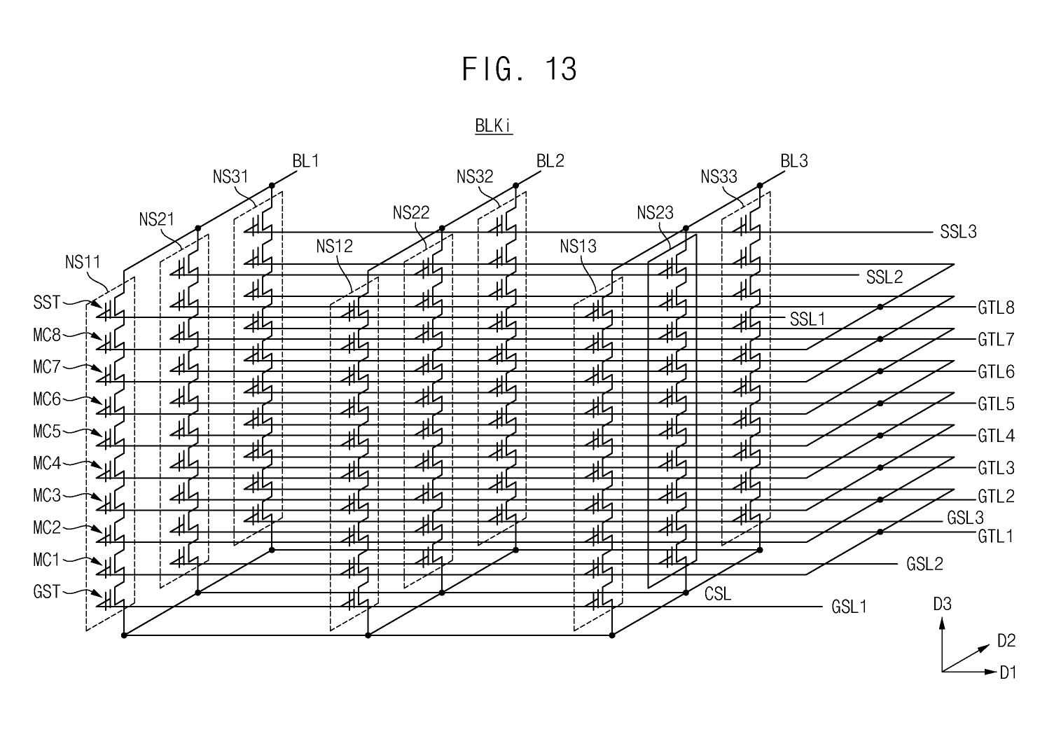

FIG. 12 is a block diagram illustrating a memory cell array included in the nonvolatile memory device of FIG. 10 according to example embodiments, and FIG. 13 is a circuit diagram illustrating an equivalent circuit of a memory block included in the memory cell array of FIG. 12 according to example embodiments.

Referring to FIG. 12, the memory cell array 500 may include memory blocks BLK1 to BLKz. In some example embodiments, the memory blocks BLK1 to BLKz may be selected by the address decoder 530 in FIG. 10. For example, the address decoder 530 may select a particular memory block BLK among the memory blocks BLK1 to BLKz corresponding to a block address.

The memory block BLKi of FIG. 13 may be formed on a substrate in a three-dimensional structure (for example, a vertical structure). For example, NAND strings or cell strings included in the memory block BLKi may be disposed in the vertical direction D3 perpendicular to the top surface of the substrate.

Referring to FIG. 13, the memory block BLKi may include cell strings or NAND strings NS11 to NS33 coupled between bitlines BL1, BL2 and BL3 and a common source line CSL. Each NAND string may include a plurality of memory cells stacked in the vertical direction D3, and the plurality of wordlines may be stacked in the vertical direction D3.

Each of the NAND strings NS11 to NS33 may include a string selection transistor SST, memory cells MC1 to MC8, and a ground selection transistor GST. In FIG. 13, each of the NAND strings NS11 to NS33 is illustrated to include eight memory cells MC1 to MC8. However, the number of memory cells is not limited thereto, and each of the NAND strings NS11 to NS33 may include any number of memory cells.

Each string selection transistor SST may be connected to a corresponding string selection line (for example, one of SSL1 to SSL3). The memory cells MC1 to MC8 may be connected to corresponding gate lines GTL1 to GTL8, respectively. The gate lines GTL1 to GTL8 may be wordlines. Some of the gate lines GTL1 to GTL8 may be dummy wordlines. Each ground selection transistor GST may be connected to a corresponding ground selection line (for example, one of GSL1 to GSL3). Each string selection transistor SST may be connected to a corresponding bitline (e.g., one of BL1, BL2 and BL3). Each ground selection transistor GST may be connected to the common source line CSL.

Wordlines (each of the gate lines GTL1 to GTL8) having the same height may be commonly connected. The ground selection lines GSL1 to GSL3 and the string selection lines SSL1 to SSL3 may be separated. In FIG. 13, the memory block BLKi is illustrated to be coupled to eight gate lines GTL1 to GTL8 and three bitlines BL1 to BL3. However, connection configurations are not limited thereto. Each memory block in the memory cell array 500 may be coupled to any number of wordlines and any number of bitlines.

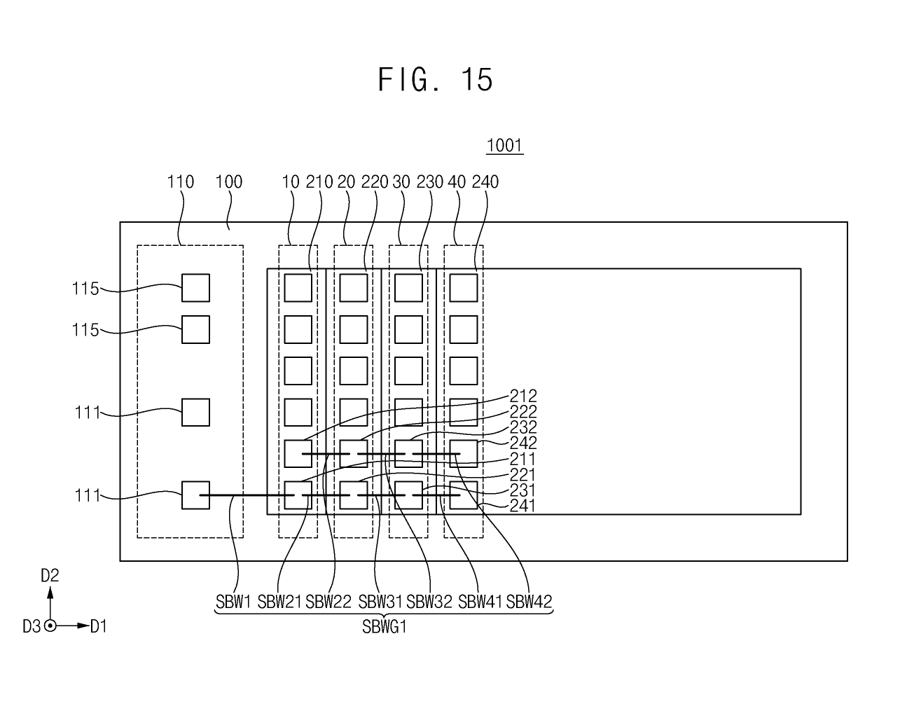

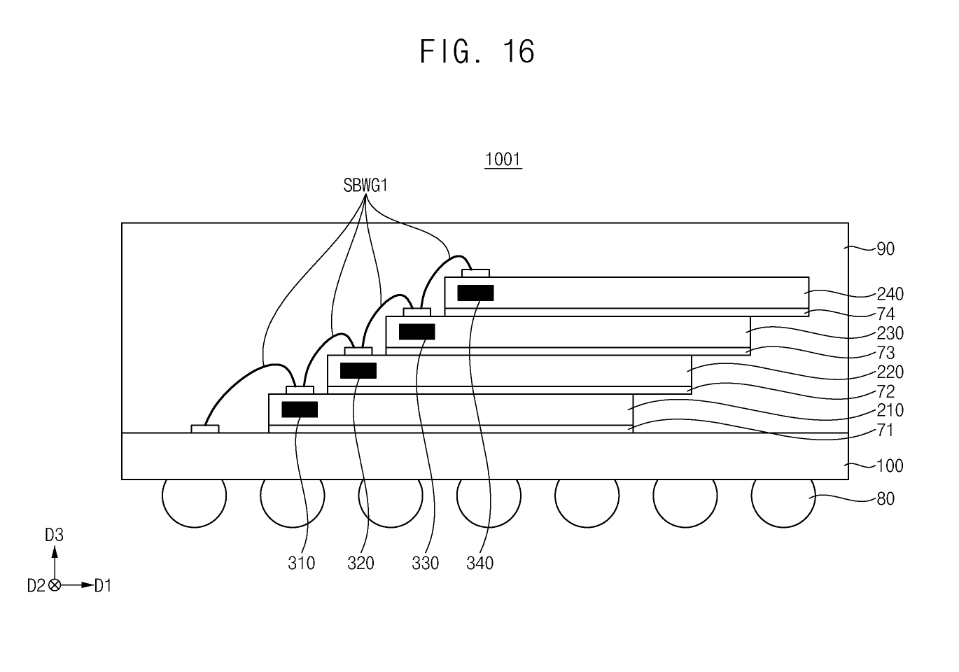

FIG. 14 is a perspective view illustrating a semiconductor memory package according to example embodiments. FIG. 15 is a plan view of the semiconductor memory package of FIG. 14 according to example embodiments, and FIG. 16 is a cross-sectional view of the semiconductor memory package of FIG. 14 according to example embodiments. Description that is redundant with FIGS. 1-7 may be omitted.

Referring to FIGS. 14-16, a semiconductor memory package 1001 may include a base substrate 100, a first semiconductor memory chip 210, a second semiconductor memory chip 220, a third semiconductor memory chip 230, and a fourth semiconductor memory chip 240.

The first semiconductor memory chip 210 may be stacked on the base substrate 100 in the vertical direction D3 and may include first chip pads 10. The first chip pads 10 may include first chip voltage pads 215 for carrying a power supply voltage or ground voltage, and first chip I/O pads 211 and 212 for transmitting and receiving signals. The first chip I/O pad 211 corresponds to a buffering chip pad and the first chip I/O pad 212 corresponds to a normal chip pad.

The second semiconductor memory chip 220 may be stacked on the first semiconductor memory chip 210 in the vertical direction D3 and may include second chip pads 20. The second chip pads 20 may include second chip voltage pads 225 for carrying a power supply voltage or a ground voltage, and second chip I/O pads 221 and 222 for transmitting and receiving signals. The second chip I/O pad 221 corresponds to a buffering chip pad and the second chip I/O pad 222 corresponds to a normal chip pad.

The third semiconductor memory chip 230 may be stacked on the second semiconductor memory chip 220 in the vertical direction D3 and may include third chip pads 30. The third chip pads 30 may include third chip voltage pads 235 for carrying a power supply voltage or ground voltage, and third chip I/O pads 231 and 232 for transmitting and receiving signals. The third chip I/O pad 231 corresponds to a buffering chip pad and the third chip I/O pad 232 corresponds to a normal chip pad.

The fourth semiconductor memory chip 240 may be stacked on the third semiconductor memory chip 230 in the vertical direction D3 and may include the fourth chip pads 40. The fourth chip pads 40 may include fourth chip voltage pads 245 for carrying a power supply voltage or ground voltage, and fourth chip I/O pads 241 and 242 for transmitting and receiving signals. The fourth chip I/O pad 241 corresponds to a buffering chip pad and the fourth chip I/O pad 242 corresponds to a normal chip pad.

The base substrate 100 and the semiconductor memory chips may be stacked using bonding layers 71, 72, 73, and 74. The first semiconductor memory chip 210 may be bonded to a top surface of the base substrate 100 via the first bonding layer 71, the second semiconductor memory chip 220 may be bonded to a top surface of the first semiconductor memory chip 210 via the second bonding layer 72, the third semiconductor memory chip 230 may be bonded to a top surface of the second semiconductor memory chip 220 via the third bonding layer 73, and the fourth semiconductor memory chip 240 may be bonded to a top surface of the third semiconductor memory chip 230 via the fourth bonding layer 74.

A first voltage bonding wire VBW1 may connect a substrate voltage pad 115 of the substrate pads 110 to which a power supply voltage or a ground voltage is applied, and a first chip voltage pad 215 of the first chip pads 10. A second voltage bonding wire VBW2 may connect the first chip voltage pad 215 of the first chip pads 10 and the second chip voltage pad 225 of the second chip pads 20. A third voltage bonding wire VBW3 may connect the second chip voltage pad 225 of the second chip pad 20 and the third chip voltage pad 235 of the third chip pad 30. A fourth voltage bonding wire VBW4 may connect the third chip voltage pad 235 of the third chip pad 30 and the fourth chip voltage pad 245 of the fourth chip pad 40.

The first voltage bonding wire VBW1, the second voltage bonding wire VBW2, the third voltage bonding wire VBW3, and the fourth voltage bonding wire VBW4 may be referred to as a voltage bonding wire group VBWG1. While one voltage bonding wire group VBWG1 is shown in FIGS. 14, 15, and 16 for convenience of illustration, the semiconductor memory package 1001 may include multiple voltage bonding wire groups having the same structure as the voltage bonding wire group VBWG1.

The semiconductor memory package 1001 may include a first signal bonding wire SBW1, a second signal bonding wire SBW21, a third signal bonding wire SBW22, a fourth signal bonding wire SBW31, a fifth signal bonding wire SBW32, a sixth signal bonding wire SBW41, and a seventh signal bonding wire SBW42.

The first signal bonding wire SBW1 may connect a substrate I/O pad 111 of the substrate pads 110 and a buffering chip pad 211 of the first semiconductor memory chip 210.

As such, the buffering chip pad 211 of the first semiconductor memory chip 210, which is disposed lowermost in the vertical direction D3 of the plurality of semiconductor memory chips 210, 220, 230 and 240, may be connected to the substrate I/O pad 111 of the base substrate 100. On the other hand, the normal chip pad 212 of the lowermost disposed first semiconductor memory chip 210 may not be connected to the substrate I/O pad 111 of the base substrate 100.

The second signal bonding wire SBW21 may connect the buffering chip pad 211 of the first semiconductor memory chip 210 and the buffering chip pad 221 of the second semiconductor memory chip 220. The third signal bonding wire SBW22 may connect the normal chip pad 212 of the first semiconductor memory chip 210 and the normal chip pad 222 of the second semiconductor memory chip 220. The fourth signal bonding wire SBW31 may connect a buffering chip pad 221 of the second semiconductor memory chip 220 and a buffering chip pad 231 of the third semiconductor memory chip 230. The fifth signal bonding wire SBW32 may connect the normal chip pad 222 of the second semiconductor memory chip 220 and the normal chip pad 232 of the third semiconductor memory chip 230. The sixth signal bonding wire SBW41 may connect a buffering chip pad 231 of the third semiconductor memory chip 230 and a buffering chip pad 241 of the fourth semiconductor memory chip 240. The seventh signal bonding wire SBW42 may connect the normal chip pad 232 of the third semiconductor memory chip 230 and the normal chip pad 242 of the fourth semiconductor memory chip 240.

As such, two semiconductor memory chips that are adjacent in the vertical direction D3 may be connected to each other by the buffering chip pads and connected to each other by the normal chip pads. For example, the buffering chip pad 221 of the second semiconductor memory chip 220 stacked on the first semiconductor memory chip 210 may be connected to the buffering chip pad 211 of the first semiconductor memory chip 210, and the normal chip pad 222 of the second semiconductor memory chip 220 may be connected to the normal chip pad 212 of the first semiconductor memory chip 210.

The first signal bonding wire SBW1, the second signal bonding wire SBW21, the third signal bonding wire SBW22, the fourth signal bonding wire SBW31, the fifth signal bonding wire SBW32, the sixth signal bonding wire SBW41, and the seventh signal bonding wire SBW42 may be referred to as a signal bonding wire group SBWG1. While one signal bonding wire group SBWG1 is shown in FIGS. 14, 15, and 16 for convenience of illustration, the semiconductor memory package 1001 may include multiple signal bonding wire groups having the same structure as the signal bonding wire group SBWG1.

According to example embodiments, at least one of a plurality of semiconductor memory chips stacked within a semiconductor memory package may include a buffer circuit. In an example embodiment, as shown in FIG. 16, the first semiconductor memory chip 210 may include the first buffer circuit 310, the second semiconductor memory chip 220 may include the second buffer circuit 320, the third semiconductor memory chip 230 may include the third buffer circuit 330, and the fourth semiconductor memory chip 240 may include the fourth buffer circuit 340. FIG. 16 illustrates an example embodiment in which the stacked semiconductor memory chips each include a buffer circuit. For example, at least one of the second buffer circuit 320 included in the second semiconductor memory chip 220, the third buffer circuit 330 included in the third semiconductor memory chip 230, and the fourth buffer circuit 340 included in the fourth semiconductor memory chip 240 may be omitted. In this case, the semiconductor memory chip including the buffer circuits may be referred to as a buffering semiconductor memory chip, and the semiconductor memory chip not including the buffer circuits may be referred to as a bypassing semiconductor memory chip.

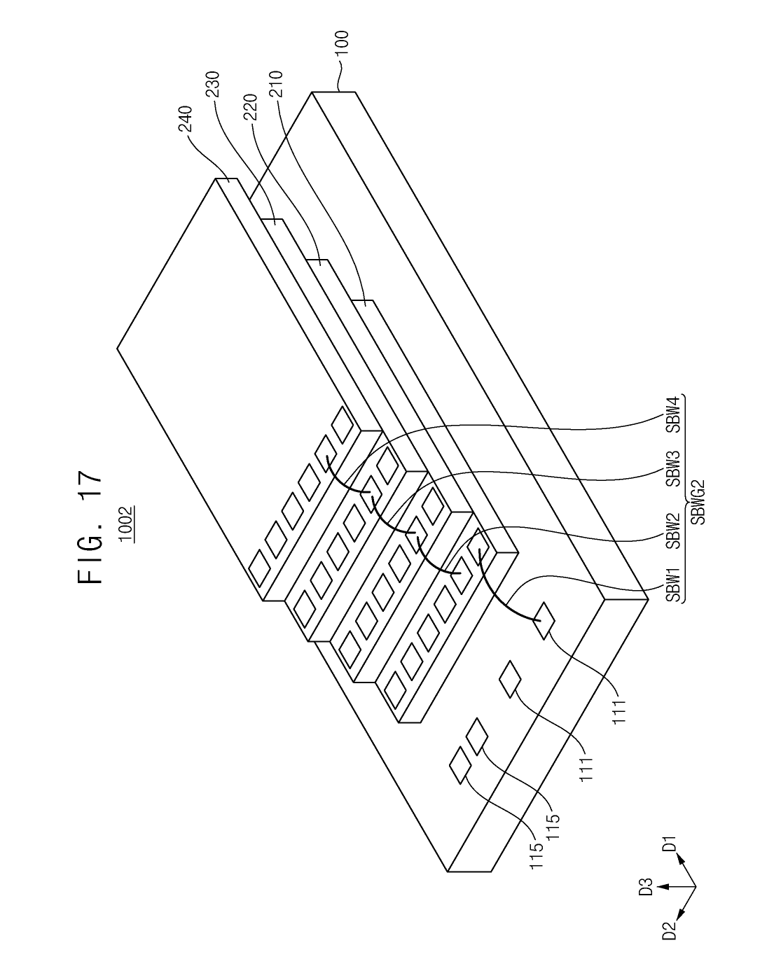

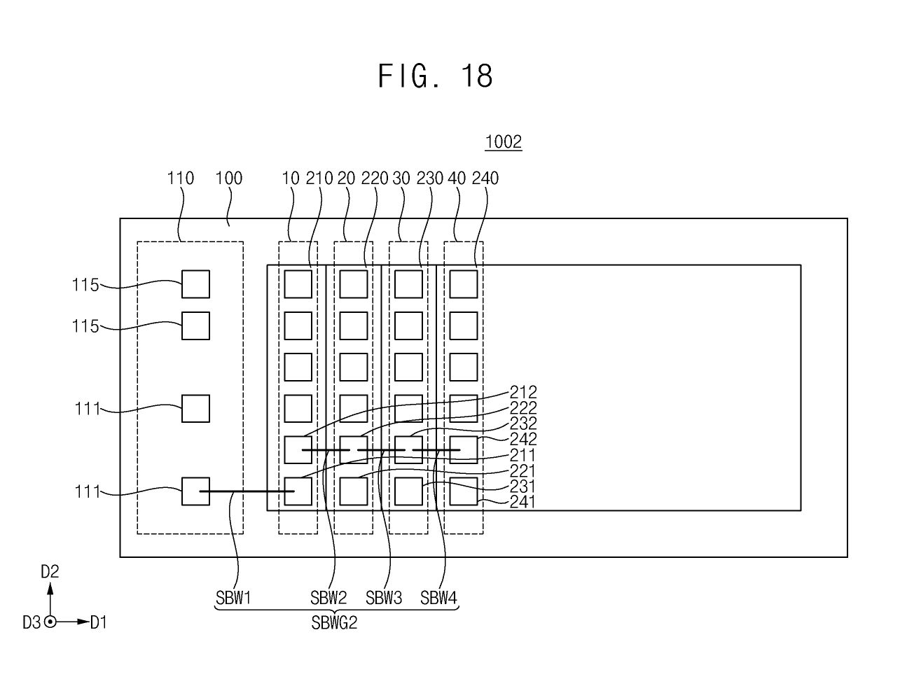

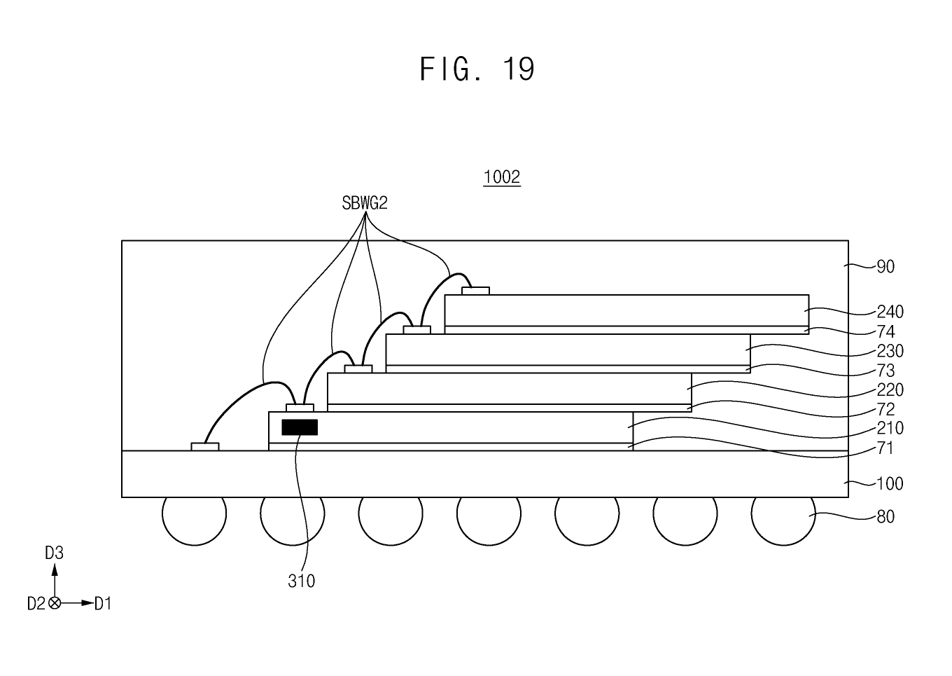

FIG. 17 is a perspective view illustrating a semiconductor memory package according to example embodiments. FIG. 18 is a plan view of the semiconductor memory package of FIG. 17 according to example embodiments, and FIG. 19 is a cross-sectional view of the semiconductor memory package of FIG. 17 according to example embodiments. The following description, which is redundant with FIGS. 1-7 and 14-16, may be omitted.

Referring to FIGS. 17-19, a semiconductor memory package 1002 may include a base substrate 100, a first semiconductor memory chip 210, a second semiconductor memory chip 220, a third semiconductor memory chip 230, and a fourth semiconductor memory chip 240.

A first signal bonding wire SBW1 may connect a substrate I/O pad 111 of the substrate pads 110 and a buffering chip pad 211 of the first semiconductor memory chip 210.

As such, the buffering chip pad 211 of the first semiconductor memory chip 210, which is disposed lowermost in the vertical direction D3 of the plurality of semiconductor memory chips 210, 220, 230 and 240, may be connected to the substrate I/O pad 111 of the base substrate 100. On the other hand, the normal chip pad 212 of the lowermost disposed first semiconductor memory chip 210 may not be connected to the substrate I/O pad 111 of the base substrate 100.

A second signal bonding wire SBW2 may connect the normal chip pad 212 of the first semiconductor memory chip 210 and the normal chip pad 222 of the second semiconductor memory chip 220. A third signal bonding wire SBW3 may connect the normal chip pad 222 of the second semiconductor memory chip 220 and the normal chip pad 232 of the third semiconductor memory chip 230. A fourth signal bonding wire SBW4 may connect the normal chip pad 232 of the third semiconductor memory chip 230 and the normal chip pad 242 of the fourth semiconductor memory chip 240.

As such, the two semiconductor memory chips adjacent in the vertical direction D3 may have the normal chip pads connected to each other and the buffering chip pads may not be connected to each other.

The first signal bonding wire SBW1, the second signal bonding wire SBW2, the third signal bonding wire SBW3, and the fourth signal bonding wire SBW4 may be referred to as a signal bonding wire group SBWG2. While one signal bonding wire group SBWG2 is shown in FIGS. 17, 18, and 19 for convenience of illustration, the semiconductor memory package 1002 may include multiple signal bonding wire groups having the same structure as the signal bonding wire group SBWG2.

According to example embodiments, at least one of the plurality of semiconductor memory chips stacked within the semiconductor memory package may correspond to a buffering semiconductor memory chip that includes buffer circuit, and the remaining semiconductor memory chips may correspond to bypassing semiconductor memory chips that do not include buffer circuit. In an example embodiment, as shown in FIG. 19, the first semiconductor memory chip 210 may correspond to a buffering semiconductor memory chip including a first buffer circuit 310, and the second semiconductor memory chip 220, the third semiconductor memory chip 230, and the fourth semiconductor memory chip 240 may correspond to bypassing semiconductor memory chips that do not include a buffer circuit. In this case, the buffering chip pads 221, 231 and 241 of the second semiconductor memory chip 220, the third semiconductor memory chip 230, and the fourth semiconductor memory chip 240 may be floated, or may be dummy pads to which a ground voltage is applied.

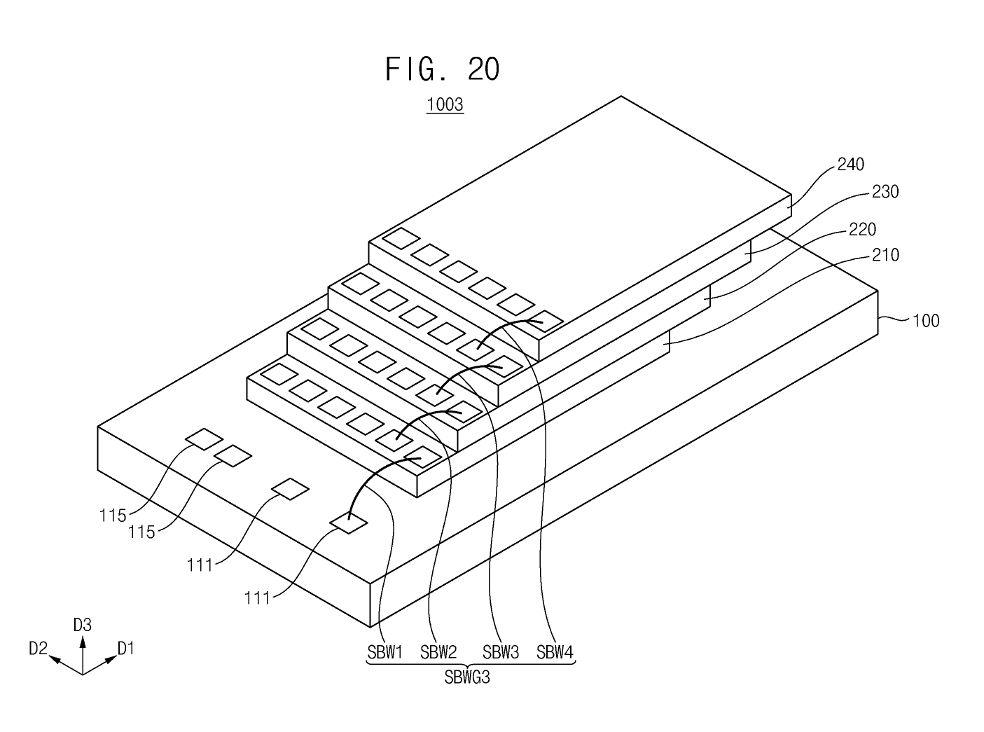

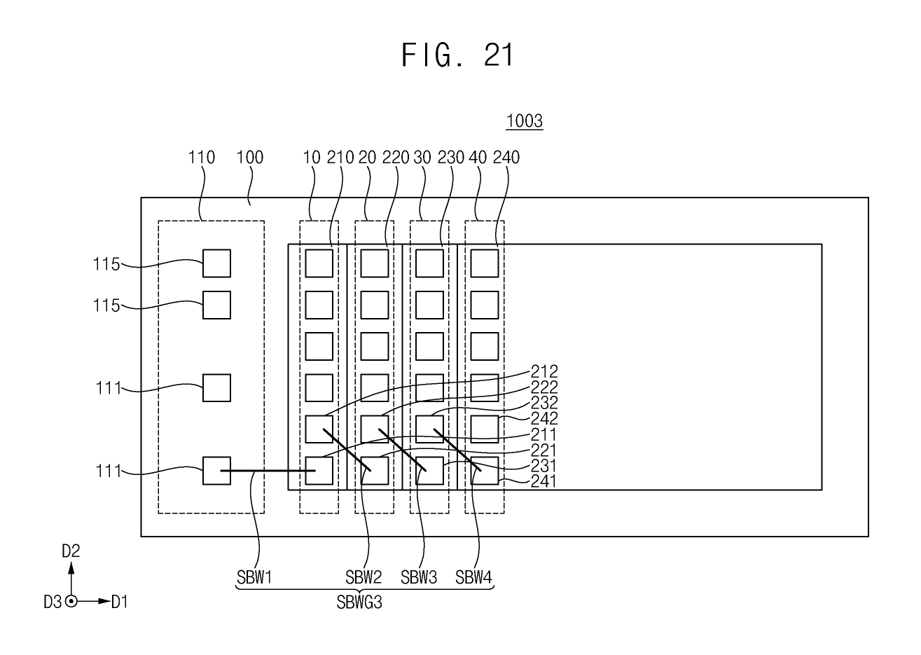

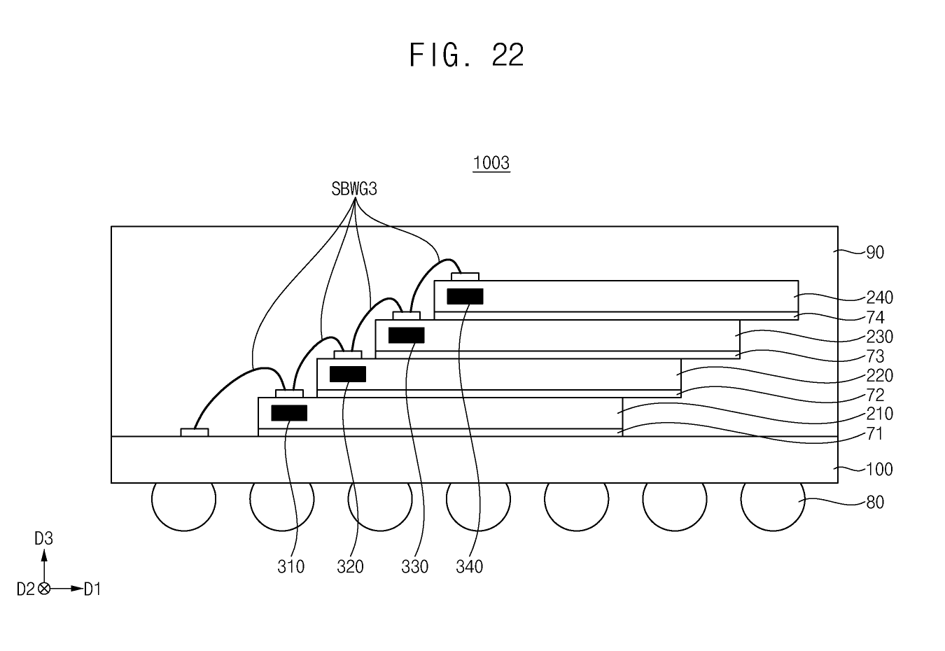

FIG. 20 is a perspective view illustrating a semiconductor memory package according to example embodiments. FIG. 21 is a plan view of the semiconductor memory package of FIG. 20 according to example embodiments, and FIG. 22 is a cross-sectional view of the semiconductor memory package of FIG. 20 according to example embodiments. Description that is redundant with FIGS. 1-7 and 14-16 below may be omitted.

Referring to FIGS. 20-22, a semiconductor memory package 1003 may include a base substrate 100, a first semiconductor memory chip 210, a second semiconductor memory chip 220, a third semiconductor memory chip 230, and a fourth semiconductor memory chip 240.

A first signal bonding wire SBW1 may connect a substrate I/O pad 111 of the substrate pads 110 and a buffering chip pad 211 of the first semiconductor memory chip 210.

As such, the buffering chip pad 211 of the first semiconductor memory chip 210, which is disposed lowermost in the vertical direction D3 of the plurality of semiconductor memory chips 210, 220, 230 and 240, may be connected to the substrate I/O pad 111 of the base substrate 100. On the other hand, the normal chip pad 212 of the lowermost disposed first semiconductor memory chip 210 may not be connected to the substrate I/O pad 111 of the base substrate 100.

A second signal bonding wire SBW2 may connect the normal chip pad 212 of the first semiconductor memory chip 210 and the buffering chip pad 221 of the second semiconductor memory chip 220. A third signal bonding wire SBW3 may connect a normal chip pad 222 of the second semiconductor memory chip 220 and a buffering chip pad 231 of the third semiconductor memory chip 230. A fourth signal bonding wire SBW4 may connect the normal chip pad 232 of the third semiconductor memory chip 230 and the buffering chip pad 241 of the fourth semiconductor memory chip 240.

As such, two semiconductor memory chips adjacent in the vertical direction D3 may be connected to each other, such that the normal chip pad of the lower semiconductor memory chip and the buffering chip pad of the upper semiconductor memory chip are connected to each other. For example, the buffering chip pad 221 of the second semiconductor memory chip 220 stacked on the first semiconductor memory chip 210 may be connected to the normal chip pad 212 of the first semiconductor memory chip 210, and the normal chip pad 222 of the second semiconductor memory chip 220 may be connected to the buffering chip pad 231 of the third semiconductor memory chip 230 stacked on the second semiconductor memory chip 220.

The first signal bonding wire SBW1, the second signal bonding wire SBW2, the third signal bonding wire SBW3, and the fourth signal bonding wire SBW4 may be referred to as a signal bonding wire group SBWG3. While one signal bonding wire group SBWG3 is shown in FIGS. 20, 21, and 22 for convenience of illustration, the semiconductor memory package 1003 may include multiple signal bonding wire groups having the same structure as the signal bonding wire group SBWG3.

According to example embodiments, the plurality of semiconductor memory chips stacked within the semiconductor memory package may all include respective buffer circuits. In other words, as shown in FIG. 22, the first semiconductor memory chip 210 may include a first buffer circuit 310, the second semiconductor memory chip 220 may include a second buffer circuit 320, the third semiconductor memory chip 230 may include a third buffer circuit 330, and the fourth semiconductor memory chip 240 may include a fourth buffer circuit 340.

FIGS. 23 and 24 are block diagrams illustrating semiconductor memory chips included in a semiconductor memory package according to example embodiments.

In FIGS. 23 and 24, a first semiconductor memory chip 210 is shown, which is a buffering semiconductor memory chip including a buffer circuit 310 for convenience of illustration and description. Other semiconductor memory chips stacked in a semiconductor memory package may be implemented in substantially the same configuration as the first semiconductor memory chip 210.

Referring to FIGS. 23 and 24, the first semiconductor memory chip 210 may include a normal chip pad 212, a buffering chip pad 211, an internal circuit 217, and a buffer circuit 310.

The internal circuit 217 may include a memory cell array MCA and a peripheral circuit PPC that controls the memory cell array MCA. The internal circuit 217 may be connected to the normal chip pad 212. Example embodiments of the configuration and operation of the internal circuit 217 are described above with reference to FIGS. 8-13.

The buffer circuit 310 may be connected between the normal chip pad 212 and the buffering chip pad 211 and may reinforce signals transferred between the normal chip pad 212 and the buffering chip pad 211. The buffer circuit 310 may selectively reinforce the signal transferred between the normal chip pad 212 and the buffering chip pad 211 based on the buffering control signal BCS1.

In an example embodiment, as shown in FIG. 23, the first semiconductor memory chip 210 may further include a buffer control portion BC 218 and a control pad 213. The control pad 213 may receive a buffer setting signal BSET transferred from a memory controller (e.g., 3100 in FIG. 8). The buffer control portion 218 may generate the buffering control signal BCS1 based on the buffer setting signal BSET, and may provide the buffering control signal BCS1 to the buffer circuit 310. The memory controller 3100 may generate the buffer setting signal BSET based on stack configuration information indicating a number of a plurality of semiconductor memory chips stacked within the semiconductor memory package and a stack position of the corresponding semiconductor memory chips 210.

In an example embodiment, as shown in FIG. 24, the first semiconductor memory chip 210 may internally generate the buffering control signal BCS1 regardless of the signals transferred from the memory controller 3100. That is, the first semiconductor memory chip 210 may not include a control pad 213 or a buffer control portion BC 218, and thus may generate the buffering control signal BCS1 without receiving a buffer setting signal BSET. For example, the peripheral circuit PPC of the first semiconductor memory chip 210 may store stack configuration information SCI indicating the number of a plurality of semiconductor memory chips stacked within the semiconductor memory package and the corresponding stack positions of the first semiconductor memory chips 210. The peripheral circuit PPC may generate the buffering control signal BCS1 based on the stack configuration information SCI, and may provide the buffering control signal BCS1 to the buffer circuit 310.

FIGS. 25, 26, 27, 28, 29, 30 and 31 are diagrams illustrating examples of controlling the operation of a semiconductor memory package according to example embodiments.

In FIGS. 25-31, BCSi (i is a positive integer) denotes a buffering control signal of the i-th semiconductor memory chip of a plurality of semiconductor memory chips stacked in the vertical direction D3. A smaller subscript i indicates a lower stack position. WOP indicates that the operation mode is a write operation, and ROP indicates that the operation mode is a read operation. As described with reference to FIG. 5, FBCSi denotes a forward buffering control signal of the i-th semiconductor memory chip and BBCSi denotes a backward buffering control signal of the i-th semiconductor memory chip. The buffering control signal BCSi may include the forward buffering control signal FBCSi and the backward buffering control signal BBCSi. For example, the buffer circuit (e.g., 310 in FIG. 5) may select an reinforcement path (e.g., PTH1 and PTH3 in FIG. 5) when the buffering control signals (e.g., FBCS1 and FBCS2 in FIG. 5) are enabled to a logic high level H and a bypass path (e.g., PTH2 and PTH4 in FIG. 5) when the buffering control signals are disabled to a logic low level L.

Referring to FIGS. 25, 26, and 27, the forward buffer circuit and the backward buffer circuit included in each semiconductor memory chip may be simultaneously enabled or simultaneously disabled regardless of operation modes WOP and ROP.

In an example embodiment, as shown in FIG. 25, buffering control signals FBCS1 and BBCS1 of the lowermost first semiconductor memory chip 210 may be enabled at a logic high level H to enable the buffer circuits 310 of the first semiconductor memory chip 210 and disable the buffer circuits 320, 330 and 340 of the remaining semiconductor memory chips 220, 230 and 240.

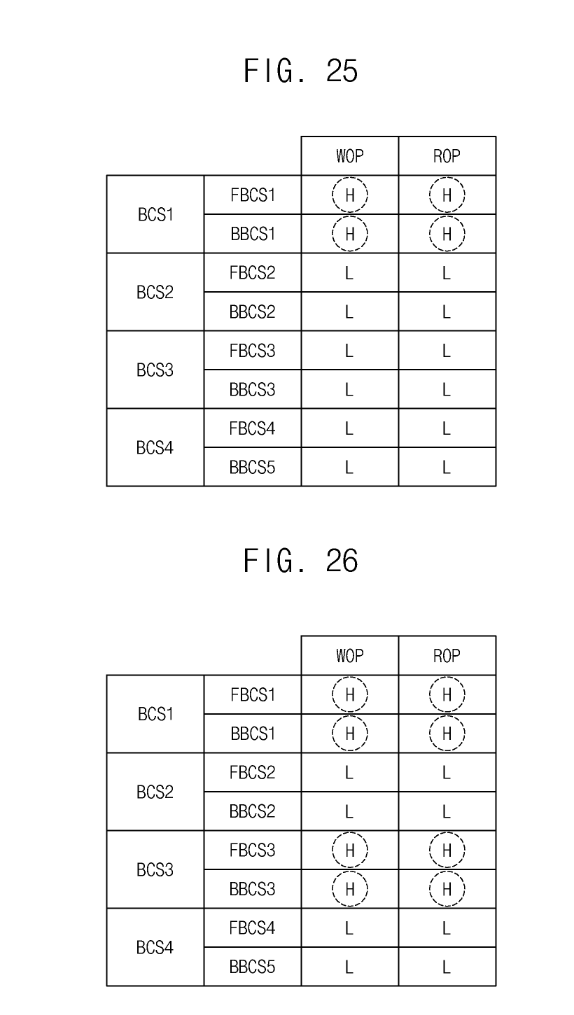

According to example embodiments, the number of semiconductor memory chips whose buffer circuits are enabled may be adjusted based on an operating frequency, an impedance in the signal path, or the like. FIG. 25 illustrates an example embodiment of enabling the buffer circuit of one semiconductor memory chip, that is, the first semiconductor memory chip 210, FIG. 26 illustrates an example embodiment of enabling the buffer circuit of two semiconductor memory chips, that is, the first semiconductor memory chip 210 and the third semiconductor memory chip 230, and FIG. 27 illustrates an example embodiment of enabling the buffer circuit of all semiconductor memory chips, that is, the first to fourth semiconductor memory chips 210, 220, 230 and 240.

Referring to FIG. 28, a buffering control signal may be generated based on operation modes WOP and ROP. In an example embodiment, in the write operation WOP, the forward buffering control signal FBCS1 of the first semiconductor memory chip 210 may be enabled and the backward buffering control signal BBCS1 may be disabled. On the other hand, in the read operation ROP, the forward buffering control signal FBCS1 of the first semiconductor memory chip 210 may be disabled and the backward buffering control signal BBCS1 may be enabled.

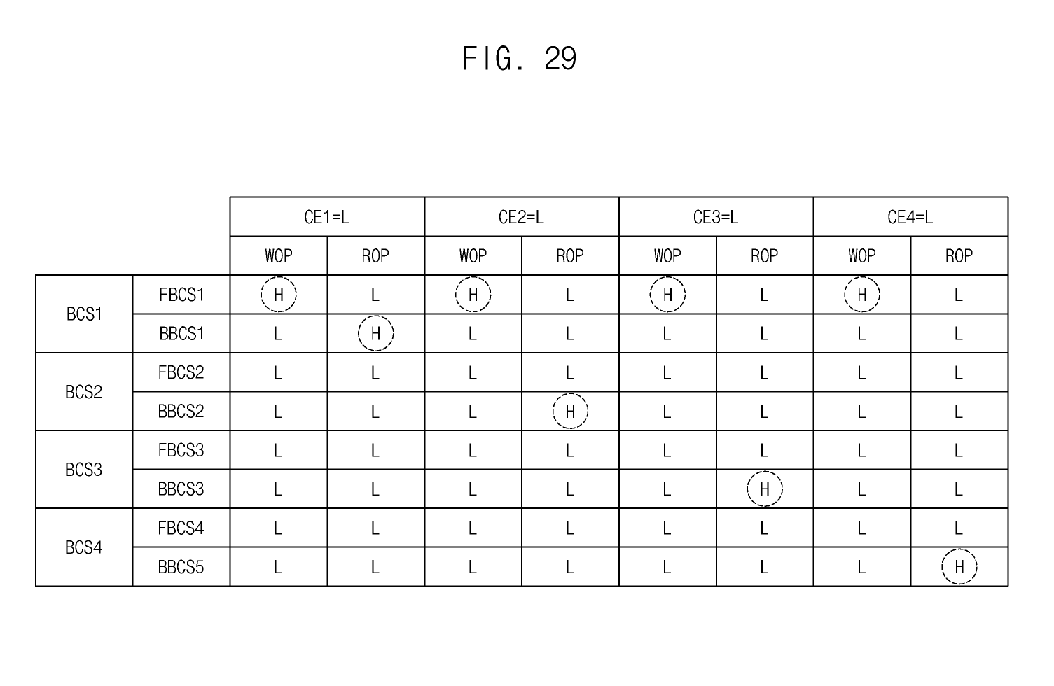

Referring to FIG. 29, each semiconductor memory chip may generate buffering control signals based on one of chip enable signals CE1 to CE4 corresponding to the semiconductor memory chip.

In the read operation ROP, only the backward buffering control signal of the selected semiconductor memory chip may be activated to enable only the backward buffer circuit of the selected semiconductor memory chip. As shown in FIG. 29, when the first semiconductor memory chip 210 is selected (CE1=L), only the backward buffering control signal BBCS1 of the first semiconductor memory chip 210 is enabled to a logic high level H, and when the second semiconductor memory chip 220 is selected (CE2=L), only the backward buffering control signal BBCS2 of the second semiconductor memory chip 220 is enabled to a logic high level H, When the third semiconductor memory chip 230 is selected (CE3=L), only the backward buffering control signal BBCS3 of the third semiconductor memory chip 230 is enabled at the logic high level H; and when the fourth semiconductor memory chip 240 is selected (CE4=L), only the backward buffering control signal BBCS4 of the fourth semiconductor memory chip 240 is enabled at the logic high level H.

On the other hand, in the write operation WOP, only the forward buffering control signal FBCS1 of the lowermost first semiconductor memory chip 210 may be enabled to logic high level H regardless of the chip enable signals CE1 to CE4.

As such, each semiconductor memory chip may generate a forward buffering signal based on the number of the plurality of semiconductor memory chips stacked and the stack position of the corresponding semiconductor memory chip, and generate a backward buffering signal based on the corresponding chip enable signal.

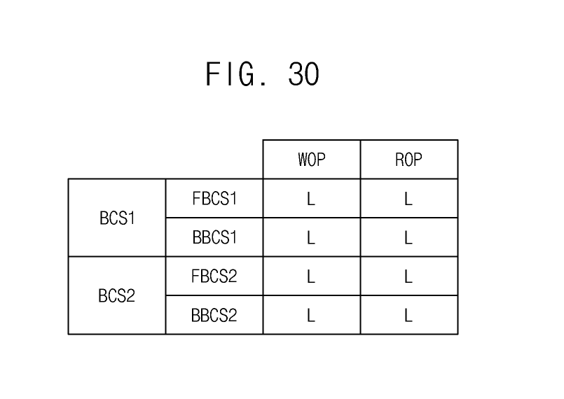

Referring to FIG. 30, if the number of semiconductor memory chips stacked in the semiconductor memory package is less than a reference number, the buffering control signals of all semiconductor memory chips may be disabled. For example, as shown in FIG. 30, when two semiconductor memory chips, such as a first semiconductor memory chip 210 and a second semiconductor memory chip 220, are stacked in the semiconductor memory package, the buffering control signals FBCS1, BBCS1, FBCS2, and BBCS2 of the first semiconductor memory chip 210 and the second semiconductor memory chip 220 may all be disabled to a logic low level L.

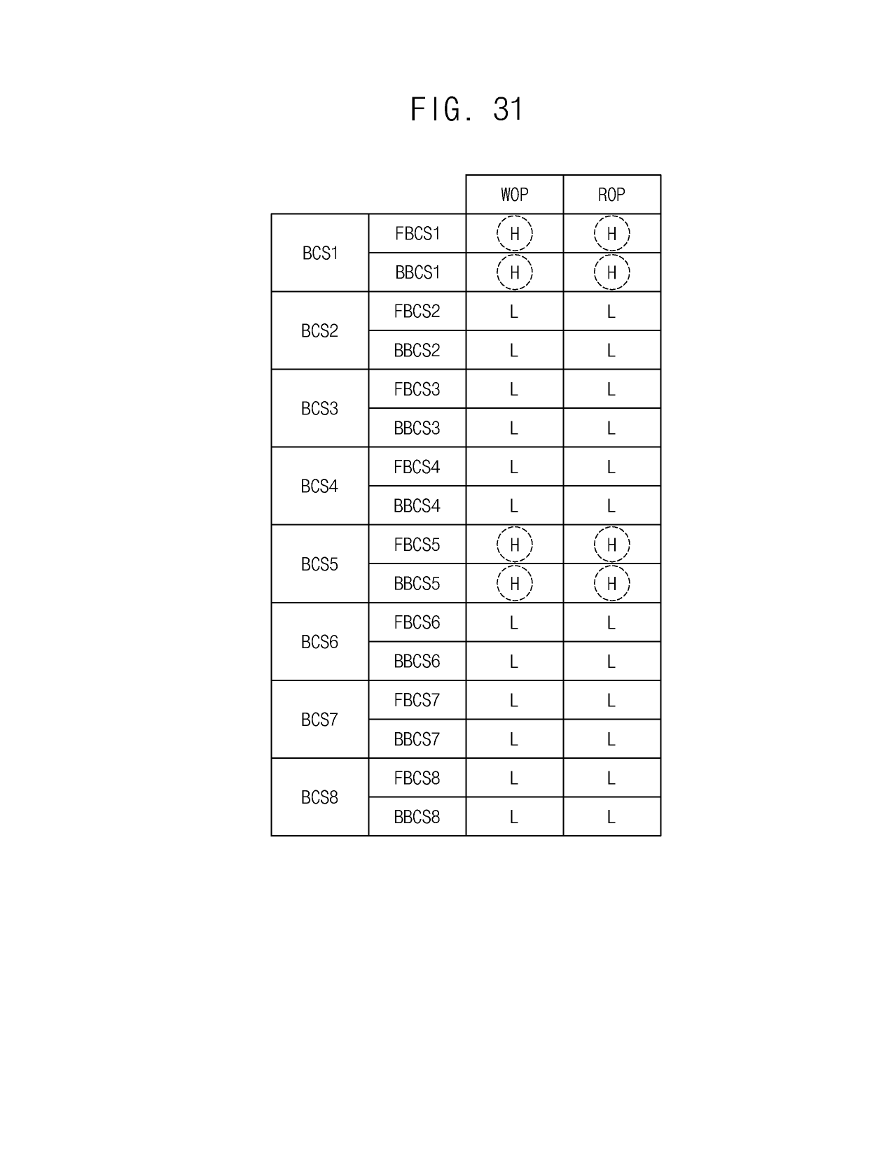

FIG. 31 illustrates an example embodiment where eight semiconductor memory chips are stacked within a semiconductor memory package. As shown in FIG. 31, the buffering control signals FBCS1 and BBCS1 of the lowermost first semiconductor memory chip and the buffering control signals FBCS5 and BBCS5 of the fifth semiconductor memory chip located in the middle in the vertical direction D3 may be enabled, and the buffering control signals of the remaining semiconductor memory chips FBCS2, BBCS2, FBCS3, BBCS3, FBCS4, BBCS4, FBCS6, BBCS6, FBCS7, BBCS7, FBCS8, and BBCS8 may be disabled to the logic low level L.

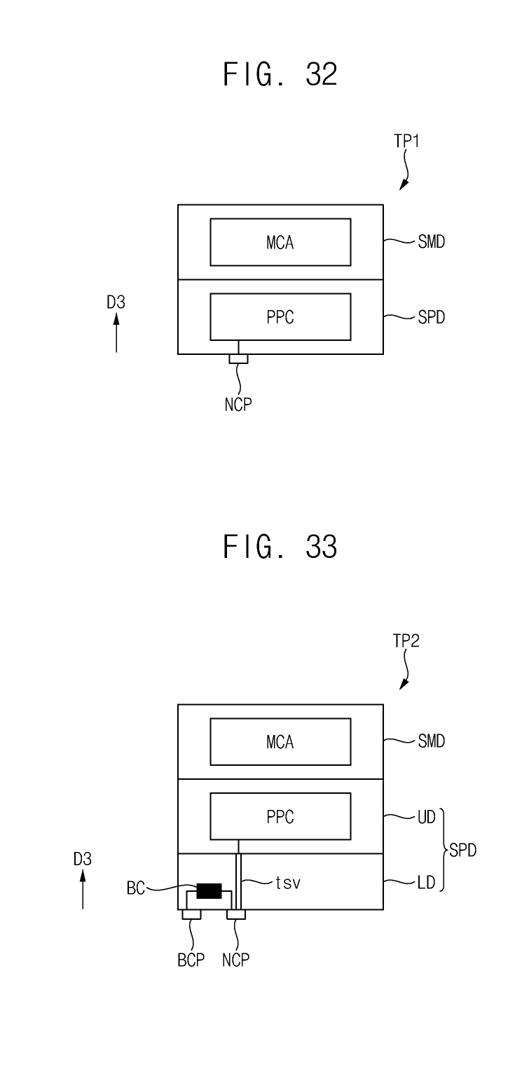

FIGS. 32 and 33 are diagrams illustrating a semiconductor memory chip included in a semiconductor memory package according to example embodiments.

Referring to FIGS. 32 and 33, the semiconductor memory chip may have a cell over periphery (CoP) structure in which a memory semiconductor die SMD including a memory cell array MCA is stacked on a peripheral circuit semiconductor die SPD including a peripheral circuit PPC in the vertical direction D3. The CoP structure will be described further with reference to FIGS. 36 and 37.

FIG. 32 illustrates a semiconductor memory chip of a first type TP1 that does not include a buffer circuit, i.e., a bypassing semiconductor memory chip, and FIG. 33 illustrates a semiconductor memory chip of a second type TP2 that includes a buffer circuit BC, i.e., a buffering semiconductor memory chip. The semiconductor memory chip of the second type TP2 may include a normal chip pad NCP and a buffering chip pad BCP connected by the buffer circuit BC as described above. On the other hand, the semiconductor memory chip of the first type TP1 may include only the normal chip pad NCP, and the buffering chip pad BCP may be omitted.

In an example embodiment, as shown in FIG. 33, a peripheral circuit semiconductor die SPD may include a lower semiconductor die LD and an upper semiconductor die UD stacked in the vertical direction D3 on the lower semiconductor die LD. A peripheral circuit PPC may be included in the upper semiconductor die UD, and a buffer circuit BC may be included in the lower semiconductor die LD. The normal chip pad NCP disposed on the surface of the lower semiconductor die LD may be connected to the peripheral circuit PPC of the upper semiconductor die UD through the through vias TSV of the lower semiconductor die LD. In some example embodiments, a portion of the peripheral circuit PPC may be disposed in the lower semiconductor die LD.

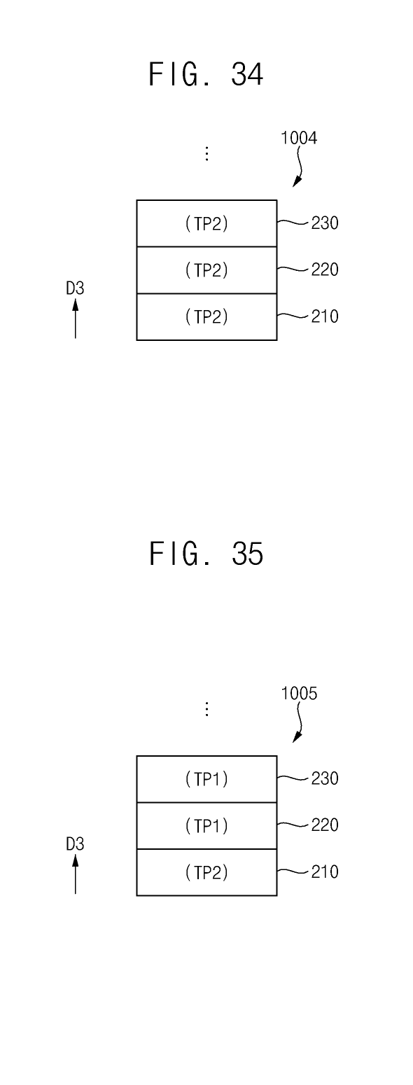

FIGS. 34 and 35 are diagrams illustrating a semiconductor memory package according to example embodiments.

Referring to FIG. 34, semiconductor memory chips 210, 220 and 230 stacked in the perpendicular direction D3 in a semiconductor memory package 1004 may all be semiconductor memory chips of the second type TP2 including buffer circuits.

Referring to FIG. 35, the lowermost semiconductor memory chip 210 of the semiconductor memory chips 210, 220 and 230 stacked in the perpendicular direction D3 in the semiconductor memory package 1004 may be implemented as a semiconductor memory chip of the second type TP2 that includes a buffer circuit, and the remaining semiconductor memory chips 220 and 230 may be implemented as semiconductor memory chips of the first type TP1 that do not include a buffer circuit.

FIG. 36 is a cross-sectional diagram illustrating a nonvolatile memory device according to example embodiments.

Referring to FIG. 36, the memory device 5000 may have a chip-to-chip (C2C) structure. At least one upper chip including a cell region and a lower chip including a peripheral circuit region PREG may be manufactured separately, and then, the at least one upper chip and the lower chip may be connected to each other by a bonding method to realize the C2C structure. For example, the bonding method may refer to a method of electrically and/or physically connecting a bonding metal pattern formed in an uppermost metal layer of the upper chip to a bonding metal pattern formed in an uppermost metal layer of the lower chip. For example, in a case in which the bonding metal patterns are formed of copper CU, the bonding method may be a Cu-Cu bonding method. Alternatively or additionally, the bonding metal patterns may be formed of other metals including, but not being limited to, aluminum (Al) or tungsten (W).

The memory device 5000 may include the at least one upper chip including the cell region. For example, as shown in FIG. 36, the memory device 5000 may include two upper chips. However, the number of the upper chips is not limited thereto. In the case in which the memory device 5000 includes the two upper chips, a first upper chip that may include a first cell region CREG1, a second upper chip that may include a second cell region CREG2 and the lower chip that may include the peripheral circuit region PREG, may be manufactured separately. Subsequently, the first upper chip, the second upper chip and the lower chip may be connected to each other by the bonding method to manufacture the memory device 5000, for example. In some example embodiments, the first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. For example, an upper portion of the lower chip may mean an upper portion defined based on a +Z-axis direction, and the upper portion of each of the first and second upper chips may mean an upper portion defined based on a -Z-axis direction in FIG. 36. However, example embodiments are not limited in this regard. For example, in some example embodiments, one of the first upper chip and the second upper chip may be turned over and then may be connected to a corresponding chip by the bonding method.

Each of the peripheral circuit region PREG and the first and second cell regions CREG1 and CREG2 of the memory device 5000 may include an external pad bonding region PA, a wordline bonding region WLBA, and a bitline bonding region BLBA.

The peripheral circuit region PREG may include a first substrate 5210 and a plurality of circuit elements (e.g., first circuit element 5220a, second circuit element 5220b, and third circuit element 5220c) formed on the first substrate 5210. An interlayer insulating layer 5215 including one or more insulating layers may be provided on the plurality of circuit elements 5220a, 5220b and 5220c, and a plurality of metal lines electrically connected to the plurality of circuit elements 5220a, 5220b and 5220c may be provided in the interlayer insulating layer 5215. For example, the plurality of metal lines may include first metal lines 5230a, 5230b and 5230c connected to the plurality of circuit elements 5220a, 5220b and 5220c, and second metal lines 5240a, 5240b and 5240c formed on the first metal lines 5230a, 5230b and 5230c. The plurality of metal lines may be formed of at least one of various conductive materials. In some example embodiments, the first metal lines 5230a, 5230b and 5230c may be formed of tungsten having a relatively high electrical resistivity, and the second metal lines 5240a, 5240b and 5240c may be formed of copper having a relatively low electrical resistivity.

The first metal lines 5230a, 5230b and 5230c and the second metal lines 5240a, 5240b and 5240c are illustrated and described in some example embodiments. However, example embodiments are not limited in this regard. For example, in some example embodiments, at least one or more additional metal lines may further be formed on the second metal lines 5240a, 5240b and 5240c. In this case, the second metal lines 5240a, 5240b and 5240c may be formed of aluminum, and at least some of the additional metal lines formed on the second metal lines 5240a, 5240b and 5240c may be formed of copper having an electrical resistivity lower than that of aluminum of the second metal lines 5240a, 5240b and 5240c.

The interlayer insulating layer 5215 may be disposed on the first substrate 5210 and may include an insulating material such as silicon oxide and/or silicon nitride.

Each of the first and second cell regions CREG1 and CREG2 may include at least one memory block. The first cell region CREG1 may include a second substrate 5310 and a common source line 5320. A plurality of wordlines 5330 (e.g., 5331 to 5338) may be stacked on the second substrate 5310 in a direction (e.g., the Z-axis direction) perpendicular to a top surface of the second substrate 5310. String selection lines and a ground selection line may be disposed on and under the wordlines 5330, and the plurality of wordlines 5330 may be disposed between the string selection lines and the ground selection line. Alternatively or additionally, the second cell region CREG2 may include a third substrate 5410 and a common source line 5420, and a plurality of wordlines 5430 (e.g., 5431 to 5438) may be stacked on the third substrate 5410 in a direction (e.g., the Z-axis direction) perpendicular to a top surface of the third substrate 5410. Each of the second substrate 5310 and the third substrate 5410 may be formed of at least one of various materials, such as, but not limited to, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CREG1 and CREG2.

In some example embodiments, as illustrated in a region ‘A1’, the channel structure CH may be provided in the bitline bonding region BLBA and may extend in the direction perpendicular to the top surface of the second substrate 5310 to penetrate the wordlines 5330, the string selection lines, and the ground selection line. The channel structure CH may include a data storage layer, a channel layer, and a filling insulation layer. The channel layer may be electrically connected to a first metal line 5350c and a second metal line 5360c in the bitline bonding region BLBA. For example, the second metal line 5360c may be a bitline and may be connected to the channel structure CH through the first metal line 5350c. The second metal line 5360c may extend in a first direction (e.g., a Y-axis direction) parallel to the top surface of the second substrate 5310.

In some example embodiments, as illustrated in a region ‘A2’, the channel structure CH may include a lower channel LCH and an upper channel UCH, which may be connected to each other. For example, the channel structure CH may be formed by a process of forming the lower channel LCH and a process of forming the upper channel UCH. The lower channel LCH may extend in the direction perpendicular to the top surface of the second substrate 5310 to penetrate the common source line 5320 and lower wordlines 5331 and 5332. The lower channel LCH may include a data storage layer, a channel layer, and a filling insulation layer and may be connected to the upper channel UCH. The upper channel UCH may penetrate upper wordlines 5333 to 5338. The upper channel UCH may include a data storage layer, a channel layer, and a filling insulation layer, and the channel layer of the upper channel UCH may be electrically connected to the first metal line 5350c and the second metal line 5360c. As a length of a channel increases, due to characteristics of manufacturing processes, it may be difficult to form a channel having a substantially uniform width. The memory device 5000, according to example embodiments, may include a channel having improved width uniformity due to the lower channel LCH and the upper channel UCH which are formed by the processes performed sequentially.

In the case in which the channel structure CH includes the lower channel LCH and the upper channel UCH as illustrated in the region ‘A2’, a wordline located near to a boundary between the lower channel LCH and the upper channel UCH may be a dummy wordline. For example, the wordlines 5332 and 5333 adjacent to the boundary between the lower channel LCH and the upper channel UCH may be the dummy wordlines. In this case, data may not be stored in memory cells connected to the dummy wordline. Alternatively or additionally, the number of pages corresponding to the memory cells connected to the dummy wordline may be less than the number of pages corresponding to the memory cells connected to a general wordline. A level of a voltage applied to the dummy wordline may be different from a level of a voltage applied to the general wordline, and thus, it may be possible to reduce an influence of a non-uniform channel width between the lower and upper channels LCH and UCH on an operation of the memory device.

In some example embodiments, the number of the lower wordlines 5331 and 5332 penetrated by the lower channel LCH may be less than the number of the upper wordlines 5333 to 5338 penetrated by the upper channel UCH in the region ‘A2’. However, example embodiments are not limited in this regard. For example, in some example embodiments, the number of the lower wordlines penetrated by the lower channel LCH may be equal to or more than the number of the upper wordlines penetrated by the upper channel UCH. Alternatively or additionally, structural features and connection relation of the channel structure CH disposed in the second cell region CREG2 may be substantially the same as those of the channel structure CH disposed in the first cell region CREG1.

In the bitline bonding region BLBA, a first through-electrode THV1 may be provided in the first cell region CREG1, and a second through-electrode THV2 may be provided in the second cell region CREG2. As illustrated in FIG. 36, the first through-electrode THV1 may penetrate the common source line 5320 and the plurality of wordlines 5330. In some example embodiments, the first through-electrode THV1 may further penetrate the second substrate 5310. The first through-electrode THV1 may include a conductive material. Alternatively or additionally, the first through-electrode THV1 may include a conductive material surrounded by an insulating material. The second through-electrode THV2 may have the same shape and structure as the first through-electrode THV1.

In some example embodiments, the first through-electrode THV1 and the second through-electrode THV2 may be electrically connected to each other through a first through-metal pattern 5372d and a second through-metal pattern 5472d. The first through-metal pattern 5372d may be formed at a bottom end of the first upper chip including the first cell region CREG1, and the second through-metal pattern 5472d may be formed at a top end of the second upper chip including the second cell region CREG2. The first through-electrode THV1 may be electrically connected to the first metal line 5350c and the second metal line 5360c. A lower via 5371d may be formed between the first through-electrode THV1 and the first through-metal pattern 5372d, and an upper via 5471d may be formed between the second through-electrode THV2 and the second through-metal pattern 5472d. The first through-metal pattern 5372d and the second through-metal pattern 5472d may be connected to each other by the bonding method.

In some example embodiments, in the bitline bonding region BLBA, an upper metal pattern 5252 may be formed in an uppermost metal layer of the peripheral circuit region PERI, and an upper metal pattern 5392 having the same shape as the upper metal pattern 5252 may be formed in an uppermost metal layer of the first cell region CREG1. The upper metal pattern 5392 of the first cell region CREG1 and the upper metal pattern 5252 of the peripheral circuit region PREG may be electrically connected to each other by the bonding method. In the bitline bonding region BLBA, the second metal line 5360c may be electrically connected to a page buffer included in the peripheral circuit region PERI. For example, some of the circuit elements 5220c of the peripheral circuit region PREG may constitute the page buffer, and the second metal line 5360c may be electrically connected to the circuit elements 5220c constituting the page buffer through an upper bonding metal pattern 5370c of the first cell region CREG1 and an upper bonding metal pattern 5270c of the peripheral circuit region PERI.

Continuing to refer to FIG. 36, in the wordline bonding region WLBA, the wordlines 5330 of the first cell region CREG1 may extend in a second direction (e.g., an X-axis direction) parallel to the top surface of the second substrate 5310 and may be connected to a plurality of cell contact plugs 5340 (e.g., 5341 to 5347). First metal lines 5350b and second metal lines 5360b may be sequentially connected onto the cell contact plugs 5340 connected to the wordlines 5330. In the wordline bonding region WLBA, the cell contact plugs 5340 may be connected to the peripheral circuit region PREG through upper bonding metal patterns 5370b of the first cell region CREG1 and upper bonding metal patterns 5270b of the peripheral circuit region PERI.

The cell contact plugs 5340 may be electrically connected to a row decoder included in the peripheral circuit region PERI. For example, some of the circuit elements 5220b of the peripheral circuit region PREG may constitute the row decoder, and the cell contact plugs 5340 may be electrically connected to the circuit elements 5220b constituting the row decoder through the upper bonding metal patterns 5370b of the first cell region CREG1 and the upper bonding metal patterns 5270b of the peripheral circuit region PERI. In some example embodiments, an operating voltage of the circuit elements 5220b constituting the row decoder may be different from an operating voltage of the circuit elements 5220c constituting the page buffer. For example, the operating voltage of the circuit elements 5220c constituting the page buffer may be greater than the operating voltage of the circuit elements 5220b constituting the row decoder.

In some example embodiments, in the wordline bonding region WLBA, the wordlines 5430 of the second cell region CREG2 may extend in the second direction (e.g., the X-axis direction) parallel to the top surface of the third substrate 5410 and may be connected to a plurality of cell contact plugs 5440 (e.g., 5441 to 5447). The cell contact plugs 5440 may be connected to the peripheral circuit region PREG through an upper metal pattern of the second cell region CREG2 and lower and upper metal patterns and a cell contact plug 5348 of the first cell region CREG1.

In the wordline bonding region WLBA, the upper bonding metal patterns 5370b may be formed in the first cell region CREG1, and the upper bonding metal patterns 5270b may be formed in the peripheral circuit region PERI. The upper bonding metal patterns 5370b of the first cell region CREG1 and the upper bonding metal patterns 5270b of the peripheral circuit region PREG may be electrically connected to each other by the bonding method. The upper bonding metal patterns 5370b and the upper bonding metal patterns 5270b may be formed of at least one metal including, but not limited to, aluminum, copper, and tungsten.

In the external pad bonding region PA, a lower metal pattern 5371e may be formed in a lower portion of the first cell region CREG1, and an upper metal pattern 5472a may be formed in an upper portion of the second cell region CREG2. The lower metal pattern 5371e of the first cell region CREG1 and the upper metal pattern 5472a of the second cell region CREG2 may be connected to each other by the bonding method in the external pad bonding region PA. In some example embodiments, an upper metal pattern 5372a may be formed in an upper portion of the first cell region CREG1, and an upper metal pattern 5272a may be formed in an upper portion of the peripheral circuit region PERI. The upper metal pattern 5372a of the first cell region CREG1 and the upper metal pattern 5272a of the peripheral circuit region PREG may be connected to each other by the bonding method.

Common source line contact plugs 5380 and 5480 may be disposed in the external pad bonding region PA. The common source line contact plugs 5380 and 5480 may be formed of a conductive material such as a metal, a metal compound, and/or doped polysilicon. The common source line contact plug 5380 of the first cell region CREG1 may be electrically connected to the common source line 5320, and the common source line contact plug 5480 of the second cell region CREG2 may be electrically connected to the common source line 5420. A first metal line 5350a and a second metal line 5360a may be sequentially stacked on the common source line contact plug 5380 of the first cell region CREG1, and a first metal line 5450a and a second metal line 5460a may be sequentially stacked on the common source line contact plug 5480 of the second cell region CREG2.

Input-output pads 5205, 5405 and 5406 may be disposed in the external pad bonding region PA. As shown in FIG. 36, a lower insulating layer 5201 may cover a bottom surface of the first substrate 5210, and a first input-output pad 5205 may be formed on the lower insulating layer 5201. The first input-output pad 5205 may be connected to at least one of a plurality of the circuit elements 5220a disposed in the peripheral circuit region PREG through a first input-output contact plug 5203 and may be separated from the first substrate 5210 by the lower insulating layer 5201. Alternatively or additionally, a side insulating layer may be disposed between the first input-output contact plug 5203 and the first substrate 5210 to electrically isolate the first input-output contact plug 5203 from the first substrate 5210.

An upper insulating layer 5401 covering a top surface of the third substrate 5410 may be formed on the third substrate 5410. A second input-output pad 5405 and/or a third input-output pad 5406 may be disposed on the upper insulating layer 5401. The second input-output pad 5405 may be connected to at least one of the plurality of circuit elements 5220a disposed in the peripheral circuit region PREG through second input-output contact plugs 5403 and 5303, and the third input-output pad 5406 may be connected to at least one of the plurality of circuit elements 5220a disposed in the peripheral circuit region PREG through third input-output contact plugs 5404 and 5304.

In some example embodiments, the third substrate 5410 may not be disposed in a region in which the input-output contact plug is disposed. For example, as illustrated in a region ‘B’, the third input-output contact plug 5404 may be separated from the third substrate 5410 in a direction parallel to the top surface of the third substrate 5410 and may penetrate an interlayer insulating layer 5415 of the second cell region CREG2 so as to be connected to the third input-output pad 5406. In this case, the third input-output contact plug 5404 may be formed by at least one of various processes.

In some example embodiments, as illustrated in a region ‘B1’, the third input-output contact plug 5404 may extend in a third direction (e.g., the Z-axis direction), and a diameter of the third input-output contact plug 5404 may become progressively greater (e.g., wider) toward the upper insulating layer 5401. In other words, a diameter of the channel structure CH described in the region ‘A1’ may become progressively less (e.g., narrower) toward the upper insulating layer 5401, but the diameter of the third input-output contact plug 5404 may become progressively greater toward the upper insulating layer 5401. For example, the third input-output contact plug 5404 may be formed after the second cell region CREG2 and the first cell region CREG1 are bonded to each other by the bonding method.

In some example embodiments, as illustrated in a region ‘B2’, the third input-output contact plug 5404 may extend in the third direction (e.g., the Z-axis direction), and a diameter of the third input-output contact plug 5404 may become progressively less (e.g., narrower) toward the upper insulating layer 5401. In other words, like the channel structure CH, the diameter of the third input-output contact plug 5404 may become progressively less (e.g., narrower) toward the upper insulating layer 5401. For example, the third input-output contact plug 5404 may be formed together with the cell contact plugs 5440 before the second cell region CREG2 and the first cell region CREG1 are bonded to each other.

In some example embodiments, the input-output contact plug may overlap with the third substrate 5410. For example, as illustrated in a region ‘C’, the second input-output contact plug 5403 may penetrate the interlayer insulating layer 5415 of the second cell region CREG2 in the third direction (e.g., the Z-axis direction) and may be electrically connected to the second input-output pad 5405 through the third substrate 5410. In this case, a connection structure of the second input-output contact plug 5403 and the second input-output pad 5405 may be realized by various methods.

In some example embodiments, as illustrated in a region ‘C1’, an opening 5408 may be formed to penetrate the third substrate 5410, and the second input-output contact plug 5403 may be connected directly to the second input-output pad 5405 through the opening 5408 formed in the third substrate 5410. In this case, as illustrated in the region ‘C1’, a diameter of the second input-output contact plug 5403 may become progressively greater (e.g., wider) toward the second input-output pad 5405. However, example embodiments are not limited in this regard. For example, in some example embodiments, the diameter of the second input-output contact plug 5403 may become progressively less (e.g., narrower) toward the second input-output pad 5405.

In some example embodiments, as illustrated in a region ‘C2’, the opening 5408 penetrating the third substrate 5410 may be formed, and a contact 5407 may be formed in the opening 5408. An end of the contact 5407 may be connected to the second input-output pad 5405, and another end of the contact 5407 may be connected to the second input-output contact plug 5403. Thus, the second input-output contact plug 5403 may be electrically connected to the second input-output pad 5405 through the contact 5407 in the opening 5408. In this case, as illustrated in the region ‘C2’, a diameter of the contact 5407 may become progressively greater (e.g., wider) toward the second input-output pad 5405, and a diameter of the second input-output contact plug 5403 may become progressively less (e.g., narrower) toward the second input-output pad 5405. For example, the second input-output contact plug 5403 may be formed together with the cell contact plugs 5440 before the second cell region CREG2 and the first cell region CREG1 are bonded to each other, and the contact 5407 may be formed after the second cell region CREG2 and the first cell region CREG1 are bonded to each other.

In some example embodiments illustrated in a region ‘C3’, a stopper 5409 may further be formed on a bottom end of the opening 5408 of the third substrate 5410, as compared with the example embodiments of the region ‘C2’. The stopper 5409 may be a metal line formed in the same layer as the common source line 5420. Alternatively or additionally, the stopper 5409 may be a metal line formed in the same layer as at least one of the wordlines 5430. The second input-output contact plug 5403 may be electrically connected to the second input-output pad 5405 through the contact 5407 and the stopper 5409.

Similar to the second and third input-output contact plugs 5403 and 5404 of the second cell region CREG2, a diameter of each of the second and third input-output contact plugs 5303 and 5304 of the first cell region CREG1 may become progressively less (e.g., narrower) toward the lower metal pattern 5371e and/or may become progressively greater (e.g., wider) toward the lower metal pattern 5371e.

In some example embodiments, a slit 5411 may be formed in the third substrate 5410. For example, the slit 5411 may be formed at a certain position of the external pad bonding region PA. For example, as illustrated in a region ‘D’, the slit 5411 may be located between the second input-output pad 5405 and the cell contact plugs 5440 in plan view. Alternatively or additionally, the second input-output pad 5405 may be located between the slit 5411 and the cell contact plugs 5440 in plan view.

In some example embodiments, as illustrated in a region ‘D1’, the slit 5411 may be formed to penetrate the third substrate 5410. For example, the slit 5411 may be used to prevent the third substrate 5410 from being finely cracked when the opening 5408 is formed. However, example embodiments are not limited in this regard. For example, in some example embodiments, the slit 5411 may be formed to have a depth ranging from about 60% to about 70% of a thickness of the third substrate 5410.

In some example embodiments, as illustrated in a region ‘D2’, a conductive material 5412 may be formed in the slit 5411. For example, the conductive material 5412 may be used to discharge a leakage current occurring in driving of the circuit elements in the external pad bonding region PA to the outside. In this case, the conductive material 5412 may be connected to an external ground line.

In some example embodiments, as illustrated in a region ‘D3’, an insulating material 5413 may be formed in the slit 5411. For example, the insulating material 5413 may be used to electrically isolate the second input-output pad 5405 and the second input-output contact plug 5403 disposed in the external pad bonding region PA from the wordline bonding region WLBA. Since the insulating material 5413 is formed in the slit 5411, it may be possible to prevent a voltage provided through the second input-output pad 5405 from affecting a metal layer disposed on the third substrate 5410 in the wordline bonding region WLBA.

In some example embodiments, the first to third input-output pads 5205, 5405 and 5406 may be selectively formed. For example, the memory device 5000 may be realized to include only the first input-output pad 5205 disposed on the first substrate 5210, to include only the second input-output pad 5405 disposed on the third substrate 5410, and/or to include only the third input-output pad 5406 disposed on the upper insulating layer 5401.

In some example embodiments, at least one of the second substrate 5310 of the first cell region CREG1 and the third substrate 5410 of the second cell region CREG2 may be used as a sacrificial substrate and may be completely and/or partially removed before and/or after a bonding process. An additional layer may be stacked after the removal of the substrate. For example, the second substrate 5310 of the first cell region CREG1 may be removed before and/or after the bonding process of the peripheral circuit region PREG and the first cell region CREG1. Subsequently, an insulating layer covering a top surface of the common source line 5320 or a conduction layer for connection may be formed. Similarly, the third substrate 5410 of the second cell region CREG2 may be removed before and/or after the bonding process of the first cell region CREG1 and the second cell region CREG2, and subsequently, the upper insulating layer 5401 covering a top surface of the common source line 5420 or a conduction layer for connection may be formed.

FIG. 37 is a diagram illustrating manufacturing processes of a nonvolatile memory device according to example embodiments.

Referring to FIG. 37, respective integrated circuits may be formed on a first wafer WF1, a second wafer WF2, and a third wafer WF3. A memory cell array including the first cell region CREG1 and the second cell region CREG2 described above may be formed on the first wafer WF1 and the second wafer WF2, and peripheral circuits may be formed on the third wafer WF3. With the integrated circuits formed on the first wafer WF1, the second wafer WF2, and the third wafer WF3, the first wafer WF1, the second wafer WF2, and the third wafer WF3 may be bonded together by a bonding method. The bonded wafers WF1, WF2 and WF3 may be cut into a plurality of chips, and each chip corresponds to a memory device 5000 including stacked semiconductor dies SD1, SD2 and SD3. A cut portion of the first wafer WF1 corresponds to the first semiconductor die SD1, a cut portion of the second wafer WF2 corresponds to the second semiconductor die SD2, and a cut portion of the third wafer WF3 corresponds to the third semiconductor die SD3. The nonvolatile memory device 5000 of FIG. 36 may be manufactured according to the manufacturing process of FIG. 37.

As described above, the semiconductor memory package according to example embodiments may reduce the size of the semiconductor memory package and improve the design margin without degrading the signal integrity of the semiconductor memory package, by removing the buffering chip and embedding the buffer circuit into the semiconductor memory chip.

Example embodiments described herein may be applied to a semiconductor package and systems including a semiconductor package. For example, example embodiments may be applied to systems such as a memory card, a SSD, an embedded multimedia card (eMMC), a mobile phone, a smart phone, a personal digital assistant (PDA), a portable multimedia player (PMP), a digital camera, a camcorder, personal computer (PC), a server computer, a workstation, a laptop computer, a digital television (TV), a set-top box, a portable game console, a navigation system, a wearable device, an internet of things (IoT) device, an internet of everything (IoE) device, an e-book, a virtual reality (VR) device, an augmented reality (AR) device, a server system, a data center, an automotive device, etc.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor memory package comprising:
a base substrate connected to a memory controller; and
a plurality of semiconductor memory chips stacked on the base substrate,
wherein a first semiconductor memory chip of the plurality of semiconductor memory chips comprises:
a first normal chip pad;
a first buffering chip pad;
an internal circuit connected to the first normal chip pad, the internal circuit comprising a memory cell array and a peripheral circuit configured to control the memory cell array; and
a buffer circuit connected between the first normal chip pad and the first buffering chip pad, the buffer circuit being configured to reinforce a signal transferred between the first normal chip pad and the first buffering chip pad.

2. The semiconductor memory package of claim 1, wherein the buffer circuit is further configured to selectively reinforce the signal transferred between the first normal chip pad and the first buffering chip pad based on a buffering control signal.

3. The semiconductor memory package of claim 2, wherein the first semiconductor memory chip is configured to generate the buffering control signal based on stack configuration information indicating a number of the plurality of semiconductor memory chips and a stack position of the first semiconductor memory chip in the plurality of semiconductor memory chips.

4. The semiconductor memory package of claim 2, wherein the first semiconductor memory chip is configured to generate the buffering control signal based on a buffer setting signal transferred from the memory controller.

5. The semiconductor memory package of claim 2, wherein the first semiconductor memory chip is configured to generate the buffering control signal internally based on stack configuration information, regardless of signals transferred from the memory controller, and
wherein the stack configuration information indicates a number of the plurality of semiconductor memory chips and a stack position of the first semiconductor memory chip in the plurality of semiconductor memory chips.

6. The semiconductor memory package of claim 2, wherein the first semiconductor memory chip is configured to generate the buffering control signal based on an operation mode of the first semiconductor memory chip.

7. The semiconductor memory package of claim 2, wherein the first semiconductor memory chip is configured to generate the buffering control signal based on a chip enable signal corresponding to the first semiconductor memory chip.

8. The semiconductor memory package of claim 1, wherein the buffer circuit comprises:
a forward buffer circuit configured to selectively reinforce a signal transferred from the first buffering chip pad to the first normal chip pad based on a forward buffering control signal; and
a backward buffer circuit configured to selectively reinforce a signal transferred from the first normal chip pad to the first buffering chip pad based on a backward buffering control signal.

9. The semiconductor memory package of claim 8, wherein the first semiconductor memory chip is configured to generate the forward buffering control signal and the backward buffering control signal based on a number of the plurality of semiconductor memory chips and a stack position of the first semiconductor memory chip in the plurality of semiconductor memory chips.

10. The semiconductor memory package of claim 8, wherein the first semiconductor memory chip is configured to generate the forward buffering control signal based on a stack position of the first semiconductor memory chip in the plurality of semiconductor memory chips, and generate the backward buffering control signal based on a chip enable signal corresponding to the first semiconductor memory chip.

11. The semiconductor memory package of claim 1, wherein the buffer circuit comprises:
a forward buffer having an output connected to the first normal chip pad;
a forward switch circuit comprising a first terminal connected to the first buffering chip pad, a second terminal connected to an input of the forward buffer, and a third terminal connected to the first normal chip pad, the forward switch circuit being configured to selectively connect the first terminal to the second terminal or the third terminal based on a forward buffering control signal;
a backward buffer having an output connected to the first buffering chip pad; and
a backward switch circuit comprising a fourth terminal connected to the first normal chip pad, a fifth terminal connected to an input of the backward buffer, and a sixth terminal connected to the first buffering chip pad, the backward switch circuit being configured to selectively connect the fourth terminal to the fifth terminal or the sixth terminal based on a backward buffering control signal.

12. The semiconductor memory package of claim 1, wherein the first buffering chip pad of the first semiconductor memory chip is connected to a substrate pad of the base substrate,
wherein the first semiconductor memory chip is lowermost among the plurality of semiconductor memory chips on the base substrate, and
wherein the first normal chip pad of the first semiconductor memory chip is not connected to the base substrate.

13. The semiconductor memory package of claim 12, wherein the plurality of semiconductor memory chips comprise a second semiconductor memory chip comprising a second buffering chip pad and a second normal chip pad,
wherein the second buffering chip pad is connected to the first buffering chip pad of the first semiconductor memory chip,
wherein the second semiconductor memory chip is stacked on the first semiconductor memory chip, and
wherein the second normal chip pad is connected to the first normal chip pad of the first semiconductor memory chip.

14. The semiconductor memory package of claim 12, wherein the plurality of semiconductor memory chips comprise a second semiconductor memory chip comprising a second buffering chip pad and a second normal chip pad, and a third semiconductor memory chip comprising a third buffering chip pad,
wherein the second buffering chip pad is connected to the first normal chip pad of the first semiconductor memory chip,
wherein the second semiconductor memory chip is stacked on the first semiconductor memory chip,
wherein the second normal chip pad is connected to the third buffering chip pad of the third semiconductor memory chip, and
wherein the third semiconductor memory chip is stacked on the second semiconductor memory chip.

15. The semiconductor memory package of claim 1, wherein one or more semiconductor memory chips of the plurality of semiconductor memory chips enable the buffer circuit to reinforce the signal transferred between the first normal chip pad and the first buffering chip pad, and other semiconductor memory chips except the one or more semiconductor memory chips disable the buffer circuit from transferring a signal that is not reinforced between the first normal chip pad and the first buffering chip pad.

16. The semiconductor memory package of claim 1, wherein the first semiconductor memory chip has a cell over periphery (CoP) structure such that a memory semiconductor die comprising the memory cell array is stacked on a peripheral circuit semiconductor die including the peripheral circuit, and
wherein the buffer circuit is disposed in the peripheral circuit semiconductor die.

17. The semiconductor memory package of claim 16, wherein the peripheral circuit semiconductor die comprises:
a lower semiconductor die; and
an upper semiconductor die on the lower semiconductor die, and
wherein the buffer circuit is in the lower semiconductor die.

18. The semiconductor memory package of claim 1, wherein the memory cell array comprises a plurality of NAND strings comprising memory cells that are disposed in a vertical direction.

19. A semiconductor memory package comprising:
a base substrate connected to a memory controller; and
a plurality of semiconductor memory chips stacked on the base substrate,
wherein the plurality of semiconductor memory chips comprise:
a buffering semiconductor memory chip comprising a buffer circuit configured to reinforce a received signal and transfer a reinforced signal to the base substrate or another semiconductor memory chip among the plurality of semiconductor memory chips; and
a bypassing semiconductor memory chip that does not comprise a buffer circuit and is configured to transfer the received signal to the base substrate or another semiconductor memory chip among the plurality of semiconductor memory chips.

20. A storage device comprising:
a semiconductor memory package; and
a memory controller configured to control the semiconductor memory package,
wherein the semiconductor memory package comprises:
a base substrate connected to the memory controller; and
a plurality of semiconductor memory chips stacked on the base substrate, and
wherein a first semiconductor memory chip of the plurality of semiconductor memory chips comprises:
a normal chip pad;
a buffering chip pad;
an internal circuit connected to the normal chip pad, the internal circuit comprising a memory cell array and a peripheral circuit configured to control the memory cell array; and
a buffer circuit connected between the normal chip pad and the buffering chip pad, the buffer circuit being configured to reinforce a signal transferred between the normal chip pad and the buffering chip pad.
